(19) United States
(12) Patent Application Publication
(10) Pub. No.: US 2024/0192283 A1
(43) Pub. Date: Jun. 13, 2024

(54) INTELLIGENT POWER ALLOCATION FOR BATTERY PACK TESTING

(71) Applicant: Keysight Technologies, Inc., Santa Rosa, CA (US)

(72) Inventors: Eric Mares, Nordrhein Westfalen (DE); Oliver Köhler, Bochum (DE); Benedikt Przybyl, Bochum (DE); Manuel Bera, Bochum (DE); Andrey Popov, Bochum (DE)

(21) Appl. No.: 18/412,957

(22) Filed: Jan. 15, 2024

Related U.S. Application Data
(63) Continuation-in-part of application No. 18/111,771, filed on Feb. 20, 2023.
(60) Provisional application No. 63/323,715, filed on Mar. 25, 2022.

(51) Int. Cl. G01R 31/396; G01R 31/36

(52) U.S. Cl. CPC G01R 31/396; G01R 31/3644

(57) ABSTRACT

A battery pack test system includes a power cluster, a power router, a power allocation manager, and a plurality of test bench control units. The power cluster includes a plurality of power units. The power allocation manager is configured to dynamically switch allocations of power from individual power units of the plurality of power units to a plurality of test channels each connected to a different device under test. The plurality of test bench control units are each configured to interface with the power router and a different corresponding device under test. Each of the test bench control units includes a plurality of measurement sensors for measuring characteristics of the corresponding device under test.

### CROSS REFERENCE TO RELATED APPLICATIONS

The present application is a continuation-in-part (CIP) application of U.S. patent application Ser. No. 18/111,771 (“the parent application”) under 37 C.F.R. § 1.53(b) filed on Feb. 20, 2023, to Andrey Popov, et al. entitled “Intelligent Power Allocation For High-Power Battery Pack Test Laboratories. The present application claims priority from the parent application under 35 U.S.C. § 120, which claims priority under 35 U.S.C. § 119(e) from commonly owned U.S. Provisional Application No. 63/323,715 filed on Mar. 25, 2022. The entire disclosures of U.S. Provisional Application No. 63/323,715 and U.S. patent application Ser. No. 18/111,771 are hereby incorporated by reference in their entirety.

### BACKGROUND

Recent developments in the automotive industry include electrification of vehicle powertrains. Batteries with high energy density and power output are needed to ensure electric vehicles (EVs) can achieve long range and high driving performance, and to ensure that the electric vehicles can be quickly charged. The development of such batteries is based on in-depth testing of individual battery cells, combined into modules and integrated battery packs, due to safety and performance requirements. To meet the demand for testing of different powertrain configurations, test laboratories use multiple test channels, which requires relatively large upfront investments in installed test equipment, grid-side power supply, and laboratory space. However, peak power levels are reached relatively rarely during endurance tests, such as during high acceleration of the electric vehicles, or during the first minutes of high-power charging, so the power equipment is not fully utilized. Operating costs for the many systems are high, whereas overall utilization is low.

In the endurance tests, individual battery packs may be subjected to load profiles for up to several weeks, and the load profiles represent typical loads on the battery packs over the lifetimes of the battery packs. Testing of battery packs for high-performance sports cars or trucks may require peak power levels of above 500 kilowatts (kW) and 1500 amperes (A) per axle. In a test lab where several battery packs are tested simultaneously, a total peak power of several megawatts may be expected.

A separate test bench system is typically dedicated to each device under test (DUT) due to complexity of the test bench system. As a result, each test bench system must also be designed for peak power, even if this only occurs occasionally. For lower powers and currents such as 270 kW and 900 A, a single test bench system may suffice.

Current solutions suffer from drawbacks such as test systems being configurable only for a specific type of device under test, test systems lacking scalability, grouped test systems lacking galvanic isolation, and test systems lacking an ability to integrate with other test systems.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is an illustrative view of a system for intelligent power allocation for high-power test laboratories, in accordance with a representative embodiment.

FIG. 2A is another illustrative view of a system for intelligent power allocation for high-power test laboratories, in accordance with a representative embodiment.

FIG. 2B is another illustrative view of a system for intelligent power allocation for high-power test laboratories, in accordance with a representative embodiment.

FIG. 3 is an illustrative view of a switchbox of a power router for intelligent power allocation for high-power test laboratories, in accordance with a representative embodiment.

FIG. 4A is an illustrative view of a switch matrix for intelligent power allocation for high-power test laboratories, in accordance with a representative embodiment.

FIG. 4B is an illustrative view of a power allocation manager for intelligent power allocation for high-power test laboratories, in accordance with a representative embodiment.

FIG. 5A, FIG. 5B and FIG. 5C are an illustrative view of a method for intelligent power allocation for high-power test laboratories, in accordance with a representative embodiment.

FIG. 6A, FIG. 6B, FIG. 6C, FIG. 6D and FIG. 6E are an illustrative view of a method for intelligent power allocation for high-power test laboratories, in accordance with a representative embodiment.

FIG. 7A show an assignment of DUT's to channels of a battery pack test system in accordance with a representative embodiment.

FIG. 7B is a simplified schematic view of channels adapted to connect power units to batteries in accordance with a representative embodiment.

FIG. 7C is a simplified schematic view of channels adapted to connect power units to batteries illustratively limited to four channels in a block of switches in accordance with a representative embodiment.

FIG. 7D is a simplified schematic view of columns adapted to connect power units to channels in accordance with a representative embodiment.

FIG. 7E is a simplified schematic view of connections limiting one power unit to one channel in accordance with a representative embodiment.

FIG. 8A is a flow-diagram of a method of selecting blocks of switches to form a switch matrix for testing a battery pack in accordance with a representative embodiment.

FIG. 8B is a simplified schematic view a switch matrix comprising six blocks of switches available to connect power units to DUT's in accordance with a representative embodiment.

FIG. 8C is a simplified schematic view a switch matrix comprising three blocks of switches available to connect power units to DUT's in accordance with a representative embodiment.

FIG. 8D is a simplified schematic view the switch matrix of FIG. 8C showing redundant blocks of switches available to connect power units to DUT's in accordance with a representative embodiment.

FIG. 8E is a simplified schematic view the switch matrix of FIG. 8D showing redundant blocks of switches available to connect power units to DUT's in accordance with a representative embodiment.

FIG. 9A is a simplified schematic view of the switch matrix of FIG. 8C having an improper connection of one power unit to two DUTs.

FIG. 9B is a simplified schematic view of the switch matrix of FIG. 8C having an all connections to one DUT disabled during service of the one DUT in accordance with a representative embodiment.

FIG. 9C is a simplified schematic view of the switch matrix of FIG. 8C having an all connections all DUTs disabled during an emergent situation in accordance with a representative embodiment.

FIG. 10A is a simplified schematic view of a connection module (C module) connected to a first switch module (S module) and optional S modules in accordance with a representative embodiment.

FIG. 10B is a simplified schematic view of first and second connection modules (C modules) connected to respective first switch modules (S modules) and optional S modules in accordance with a representative embodiment.

FIG. 10C is a simplified schematic view of first and second connection modules (C modules) connected to respective first switch modules (S modules) and optional S modules in accordance with a representative embodiment.

FIG. 11A is a perspective view of a switch module comprising two 4×3 mounting plates in accordance with a representative embodiment.

FIG. 11B is a perspective view of a mounting plate shown in FIG. 11A.

FIG. 12A is a perspective view of the switch module of FIG. 11A connected to a connection module of a representative embodiment.

FIG. 12B is a perspective view of multiple switch modules connected to a connection module in accordance with a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only, and is not intended to be limiting. As used in the specification and appended claims, the singular forms of terms ‘a’, ‘an’ and ‘the’ are intended to include both singular and plural forms, unless the context clearly dictates otherwise. Additionally, the terms “comprises”, and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to”, “coupled to”, or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

As described herein, power units in a test facility may be clustered in a power cluster, and a power router may be configured to physically switch power outputs of the power units to where the power is needed. Power from power units may be intelligently and dynamically allocated to the test channels.

In accordance with a representative embodiment, a battery pack test system, comprises: a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test (DUT); a plurality of test bench control units each configured to interface with the power router and a different corresponding device under test, and each comprising a plurality of measurement sensors for measuring characteristics of the corresponding DUT; and a switch matrix comprising blocks of switches having a predetermined number of columns and a predetermined number of rows. Each row provides connections to a DUT and each column provides connections to one of the individual power units, so that no two DUT's are connected together.

In accordance with another representative embodiment, a battery pack test system, comprises: a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test (DUT); a plurality of test bench control units each configured to interface with the power router and a different corresponding device under test, and each comprising a plurality of measurement sensors for measuring characteristics of the corresponding DUT; and a switch module comprising a switch matrix comprising blocks of switches having a predetermined number of columns and a predetermined number of rows. Each row provides connections to a DUT and each column provides connections to one of the individual power units, so that no two DUT's are connected together.

In accordance with another representative embodiment, a system for testing batteries, the system comprises: a connection bench adapted to provide electrical signals to a device under test (DUT); a first switching bench comprising a first plurality of inputs and adapted to transfer electrical power selectively to the connection bench; and a second switching bench comprising a second plurality of inputs and adapted to transfer electrical power selectively to the connection bench, wherein the first switching bench and the second switching bench are modules stored in a switching cabinet.

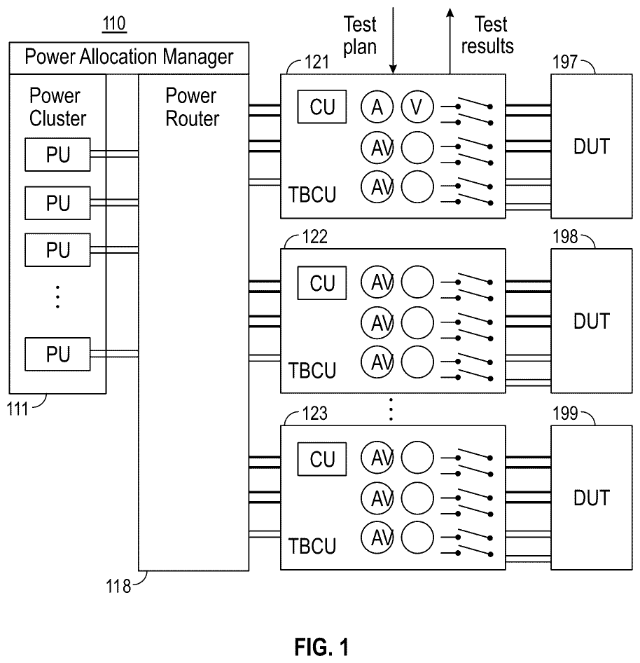

FIG. 1 is an illustrative view of a system for intelligent power allocation for high-power test laboratories, in accordance with a representative embodiment.

The system of FIG. 1 includes a power allocation manager 110 (which may be referred to as battery pack test system) and a plurality of test bench control units. For ease of illustration only three test bench units are shown. Specifically, a first test bench control unit 121, a second test bench control unit 122 and a third test bench control unit 123 are shown. The first test bench control unit 121 is interfaced with a first device under test (DUT) 197. The second test bench control unit 122 is interfaced with a second device under test (DUT) 198. The third test bench control unit 123 is interfaced with a third device under test (DUT) 199.

The power allocation manager 110 includes a power cluster 111 and a power router 118. The power cluster 111 includes a plurality of power units (PUs). Each power unit may individually provide power to some of the devices under test in FIG. 1. As an example, each individual power unit may provide 90 kilowatts (kW), 1500 volts (V), and 300 amperes (A). In other examples, a power unit may provide 20 kilowatts or 30 kilowatts. The power router 118 may include a programmable logic controller and a plurality of physical switches that are controlled by the programmable logic controller. The plurality of physical switches in the power router 118 is controlled by the programmable logic controller to switch power from the power units of the power cluster 111 to the devices under test.

As described more fully below, the power allocation manager 110 may include a programmable controller. The intelligence of the routing is in the power allocation manager. The power allocation manager (PAM) may include a programmable controller. The programmable controller may include a memory that stores instructions and a processor that executes the instructions. A routing algorithm executed by the programmable controller may provide for planning and executing optimal routing of the power provided by the power units in the power cluster 111 to the devices under test, in terms of minimal re-routing needed and satisfied power demands. The programmable controller may be configured to receive power requests from each of the test bench control units, generate an optimal routing plan for allocating power from the individual power units of the plurality of power units in the power cluster 111 to plurality of test channels to the devices under test. The programmable logic controller in the power router 118 may be configured to dynamically control the plurality of switches based on the optimal routing plan. Notably, the controller in the PAM commands the programmable logic controller (PLC) in the power router, which in turn commands the switches. The reason that PAM does not control these switches directly, but over the PLC in the power router, is because the PLC brings robustness and safety (due to implementation of the PLC), which allows monitoring switches and avoiding accidental opening/closing of switches.

A test plan may serve as the basis for the routing of power to any device under test from the power units of the power cluster 111. The devices under test may be provided power simultaneously from the power units of the power cluster 111 based on dynamic configurations and reconfigurations of the switches in the power router 118 based on the test plans for the devices under test. As described more fully below, the test plan may be a server-based test plan that is uploaded to the individual test bench control units (TBCUs) based on the types of devices under test to be tested. Accordingly, a TCBU 121 may implement different test plans at different times for different devices under test, A server (not shown) may store a set of test plans for the laboratory that includes the system of FIG. 1. A test plan may specify how much power is to be provided to a device under test, which channel is to be used to provide the power to the device under test at any one time, and how long the power is to be provided to a channel. The amount of power to be provided to any channel to a device under test may correspond to the number of power units to be used. In some embodiments, some power units may provide a first level of power, and other power units may provide a second level of power, different from the first, so that the amount of power to be provided is not strictly a linear function of the number of power units providing power. The test plan may specify amounts of power and lengths of time to provide the power by output locations corresponding to channels.

Each of the plurality of test bench control units includes a control unit (CU). Each TBCU 121 allows grouping and placement of relevant measurements and communication modules required for testing a corresponding device under test close to the corresponding device under test, such as on the side of the climate chamber closest to the device under test in the climate chamber. That is, required measurements and control for a device under test may be provided inside the corresponding test bench control unit rather than from any particular power unit, and power units may be dynamically allocated and re-allocated to different test bench control units and corresponding devices under test. A single test bench control unit may control several channels, such as several channels of a device under test. Each device under test may be provided with its own test bench control unit. Each of the plurality of test bench control units may be reconfigurable to adapt to multiple different devices under test. For example, different devices under test may have different power requirements and different numbers of channels, so each test bench control unit may be configured differently for each of multiple different devices under test at different times.

Modern battery packs typically have 2 to 5 output channels. The 2 to 5 outputs may include 2 outputs for the drive axles including one output for the front wheels one output for the rear wheels, as well as a high-power DC-charging channel, an output to onboard power consumers such as compressors, seat heating, etc., and one output to the onboard charger. The plurality of devices (DUTs) under test (e.g., first DUT 197, second DUT 198 and third DUT 199) may each comprise a battery pack with a plurality of individual battery cells. Each of the plurality of DUTs may have several high-power channels for the front and rear axle and for high-power charging, and one or more low power channels for onboard consumer electronics and chargers.

Using the configuration in FIG. 1, most or all power units of the power cluster 111 do not have to be dedicated to a specific channel on a permanent or semi-permanent basis. Additionally, the maximum power and current of each power unit may be selected such as to allow optimal quantization of step sizes and minimized hardware costs, in order to implement test plans for the devices under test. The number of power units may be variable, such as based on the requirements of the devices under test, and may be scalable. Additionally, power units may be deactivated when appropriate, such as if a power unit becomes defective, and power may be provided from another of the power units.

When devices under test vary at different times, such as with a different number of channels, current or power ratings, or specific requirements is present, only the test bench control units may require adaption for each device under test. That is, the test bench control units may be configurable and reconfigurable for different types of devices under test at different times.

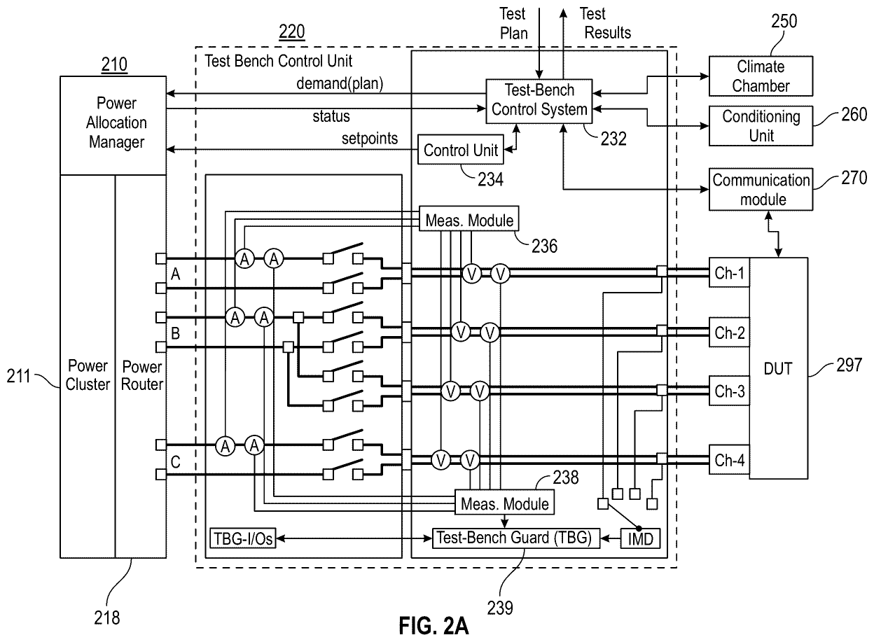

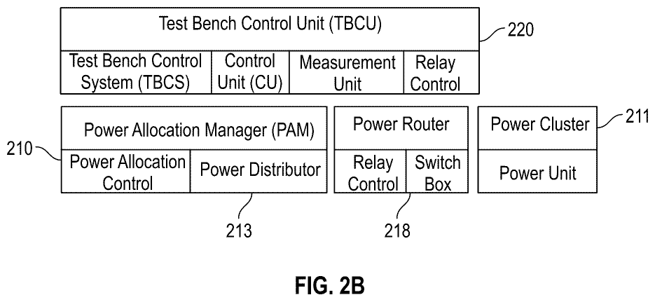

FIG. 2A is another illustrative view of a system for intelligent power allocation for high-power test laboratories, in accordance with a representative embodiment.

The system of FIG. 2A includes a power allocation manager 210, a test bench control unit 220, a climate chamber 250, a conditioning unit 260, and a communication module 270 (providing controller area network module or automotive Ethernet module). The test bench control unit 220 and the communication module 270 are interfaced with a device under test 297.

The power allocation manager 210 includes a power cluster 211 and a power router 218. The power cluster 211 includes a plurality of power units. The power router 218 includes a plurality of switches and routes power from each of the plurality of power units in the power cluster 211. The power allocation manager 210 may include some or all features and characteristics of the power allocation manager 110 in FIG. 1.

The test bench control unit 220 includes a test-bench control system 232, a control unit 234, a measurement module 238 and a test-bench guard 239 (TBG). The test bench control unit 220 may include sets of current sensors, voltage sensors and measurement modules. One set of such sensors may provide measurements for the current and voltage measurement and control. Another set of such sensors may possess relatively-lower accuracy and be used for redundant measurements for safety monitoring, and may be connected to a programmable logic controller that takes the role of a test-bench guard (TBG). The test-bench guard in the test bench control unit 220 may be implemented as safety logic executed by a processor. The test-bench guard monitors critical parameters of the battery pack, including voltage, temperature, and current, independently of the test plan. In a critical situation, the test-bench guard may be responsible for disconnecting all power contactors and bringing the system of FIG. 2A to a safe state both for the device under test and for the operating personal. An insulation monitoring device (IMD) may also be connected to the test-bench guard. Since all channels of the device under test are connected to the same battery pack inside the device under test, the insulation monitoring device may only need to monitor one of the channels.

In accordance with another representative embodiment, a battery pack test system, comprises: a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test (DUT); a plurality of test bench control units each configured to interface with the power router and a different corresponding device under test, and each comprising a plurality of measurement sensors for measuring characteristics of the corresponding DUT; and a switch module comprising a switch matrix comprising blocks of switches having a predetermined number of columns and a predetermined number of rows, wherein each row provides connections to a DUT and each column provides connections to one of the individual power units.

The climate chamber 250 is a chamber in which the device under test is placed. The climate chamber 250 and any other climate chamber described herein may emulate environmental conditions, such as temperature and humidity.

The conditioning unit 260 serves as the cooling medium for the corresponding device under test.

The communication module 270 provides a combined hardware and software communication hub as a communication interface between the test bench control unit 220 and the device under test 297. As an example, to the communication module 270, the communication module 270 may provide controller area network (CAN) interface to the device under test.

FIG. 2B is another illustrative view of a system for intelligent power allocation for high-power test laboratories, in accordance with a representative embodiment.

The system in FIG. 2B includes a power allocation manager 210 (PAM), a test bench control unit 220, a power cluster 211 and a power router 218. The power cluster 211 and the power router 218 are shown separate from the power allocation manager 210, but may be components of the power allocation manager 210.

The power allocation manager 210 includes a power allocation controller (power allocation control module) and a power distributor 213 (power distribution module). The power allocation control module may include a software program with one or more algorithms provided as logical instructions for each step of a test plan, including how much power to provide in total, how many and which power units to use to provide the power, and how long the power is to be provided. The power distributor 213 may include a software program with one or more algorithms provided as logical instructions for controlling the communication of real-time measurements and control signals between the control units in the TBCUs 220 and the power units in the power cluster 211. When executed by a processor in the power allocation manager 210, the power allocation manager 210 illustratively may generate a test plan for controlling power allocation, and then implement the test plan by controlling power distribution by controlling switched in the power router 218.

The power router 218 includes a relay control module and a switch box. The switch box includes the switches of the power router 218. The switch box may include a matrix of switches that can be used to connect some or all of the power units to some or all of the devices under test. The relay control module (the programmable logic controller described above) may control connection and disconnection of power to the power router 218 from the power units.

A capability to connect a power unit (PU) of the power cluster 211 to a particular input of a specific test bench control unit is provided for the power router 218. That is, the power router 218 may have a structure similar to a traditional signal multiplexer, but for much higher currents, with two-pole switching, having requirements to perform switching and avoid shorting two devices under test, and requiring a minimized number of switches (power contactors).

The test bench control unit 220 includes a test bench control system (TBCS), a control unit (CU), a measurement unit and a relay control. The test bench control system may be implemented on an industrial personal computer (IPC) with a Linux operating system. The test bench control system may include test bench control software that is executed to control tests for a corresponding device under test in accordance with a test plan. The control unit may include a microcontroller, such as with an real-time operating system (RTOS), and a field-programmable gate array which implement control loops of voltage and current in real time. The test bench control software may be executed to interpret the test plan and send required source-operation commands to the control unit, and may also control other systems such as the climate chamber where the device under test is placed, a conditioning unit for a cooling medium, and the communication module that provides a communication interface to the device under test. The measurement unit may include instruments used to measure characteristics of the corresponding device under test as the test plan is implemented. The relay control may control connection and disconnection of power from the power router 218 to the corresponding device under test.

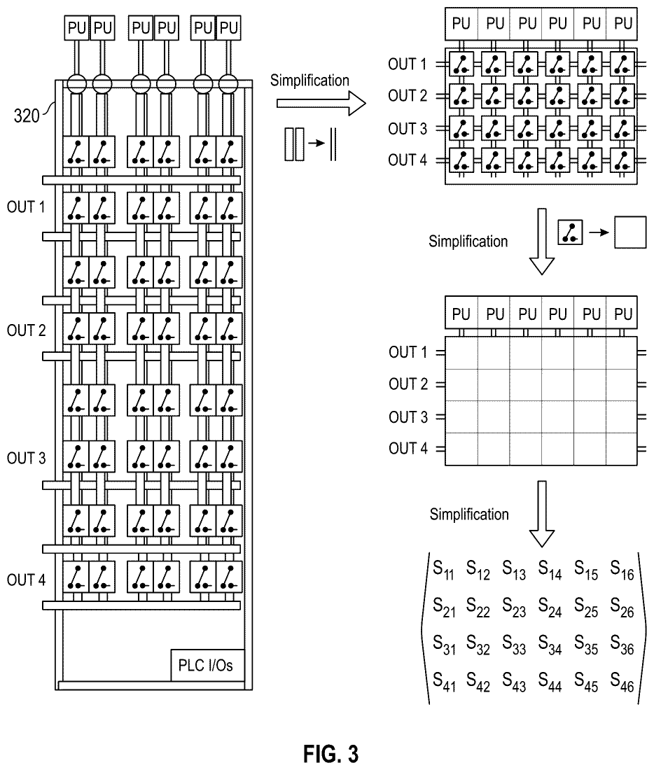

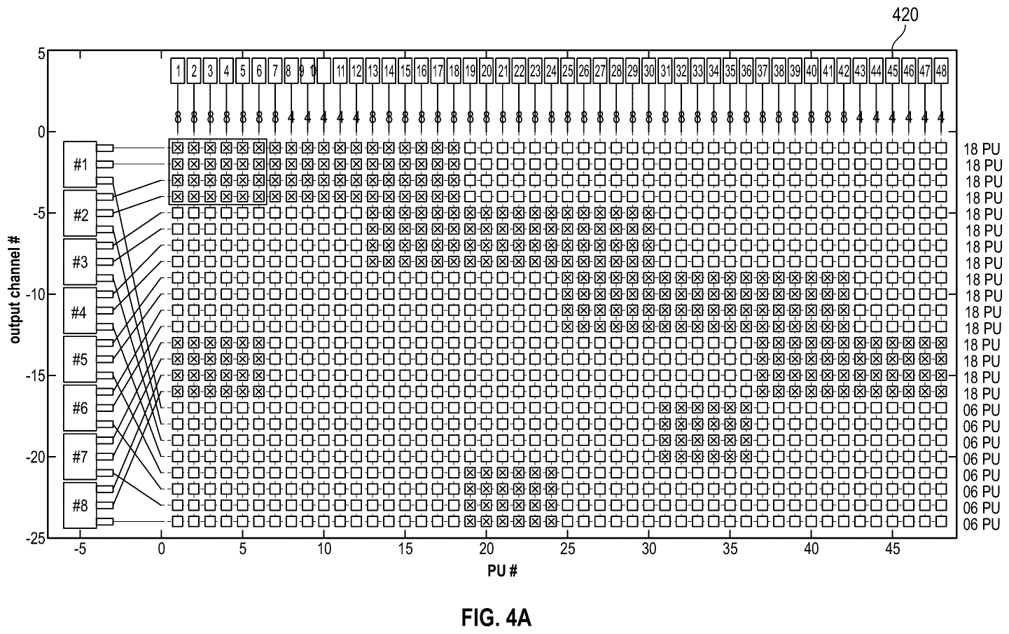

FIG. 3 is an illustrative view of a switch box of a power router for intelligent power allocation for high-power test laboratories, in accordance with a representative embodiment.

The switch box in FIG. 3 is a power switch box, and is shown in a progression of simplifications so that connection of the power units as inputs to the outputs to the test bench control units can be represented as a matrix. Each element of the matrix represents the state sᵢⱼ∈0, 1 of the corresponding switch in the switch box.

The simplifications of the power switchbox in FIG. 3 provide for a representation of connections between the power units and the test bench control units as a single switch matrix. This, in turn, provides for a representation of the connections between the power units and the device(s) under test. The overall switch matrix may be filled relatively sparsely, so that no connection from any power unit to any channel of a test bench control unit is shown, and this may reduce the hardware required inside a power router such as the power router 218. The switch matrix may be filled relatively sparsely, but as a consideration of a lower bound, a certain number of connections may be required to meet a peak power demand, and a redundancy to compensate for failures in power units may also be built into the switch matrix. The switch matrix representation may be used to identify optimal routing from the power units to the device(s) under test.

In the example of FIG. 3, the representation of the power switch box (PSB) has 6 two pole inputs connected to 6 power units, and any of the two pole inputs may be connected to any of 4 outputs. The power switch box comprises a cabinet for the power units. Two or more power switch boxes may be stacked together to scale to higher currents and power. Output busbars of two or more stacked power switch boxes may be connected. Power contactors may be used as the switching elements, and may include signal contactors that are forcibly driven and that can be monitored by the programmable logic controller (PLC) of the relay control of the power router 218. The power switch box may be a component of a power router, such as the power router 218 in FIG. 2A

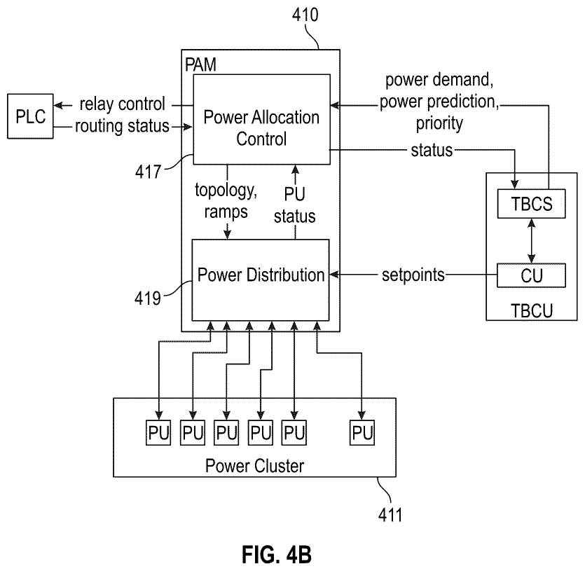

FIG. 4A is an illustrative view of a switch matrix for intelligent power allocation for high-power test laboratories, in accordance with a representative embodiment.

The switch matrix in FIG. 4A may be provided inside a power router, such as the power router 218 in FIG. 2A The switch matrix may represent interconnections between power units of the power cluster such as the power cluster 211 and channels of the device(s) under test.

As an example, a laboratory may have 8 devices under test, each with 3 channels. The 3 channels may include 2 high power channels and 1 low power for each device under test. Altogether 48 power units are provided as shown in FIG. 4A. The devices under test are shown on the left side of FIG. 4A and the power units on the top. The blocks with an “x” show the locations where a (two pole) switch is present. A power switch box with 4 outputs and 6 inputs, as the one in FIG. 3, is shown in the upper left corner. The numbers on the lines to the power unit and the right end of the diagram show the number of connections in the line. Note that channel number 3 of each device under test is the low power channels and thus connected to fewer power units, as shown in the bottom 8 rows. This representation of the power router 218 serves as an intuitive representation of an overall switch matrix.

FIG. 4B is an illustrative view of a power allocation manager for intelligent power allocation for high-power test laboratories, in accordance with a representative embodiment.

As shown in FIG. 4B, the power allocation manager 410 includes a power allocation control module 417 and a power distribution module 419. Power units are provided in a power cluster 411. The structure of the power allocation manager (PAM) and the interface to the power units in the power cluster 411 and a test bench control unit with a best bench control system and a control unit (CU) are shown. The power allocation manager in FIG. 4B is logically divided between the power allocation control module and the power distribution module.

The power allocation control module 417 receives power demands from the software of the test bench control systems, inside the test bench control units 220 in FIG. 2B, plans the optimal routing strategy, and commands the optimal routing strategy to a programmable logic controller (PLC) controlling the switches inside a power router such as the power router 218 in FIG. 2A, as well as to the power distribution module 419. The power allocation manager 410 is configured to dynamically re-route power, within the constraints of the power units, and the number of switching cycles the contactors inside the power router can withstand. Power allocation for a test plan may be calculated and recalculated with a sample time between 10 seconds and 5 minutes, for example.

The power demand may be determined based on the test plan. The test bench control systems may check the test step(s) before implementation. Relevant test steps are the ones that require a source to be active. Examples of these are current, voltage or power source, AC-signal measurements and constant current, and constant voltage (CCCV) charging. For the first three types of test step, the current and power demand may be readily computed by the test step parameters and the current state of the device under test.

For example, before activation of a channel in current source mode the parametrized current setpoint may be extracted from the test step. Multiplying this by the voltage of the device under test provides the power. Additionally, variation in the voltage of the device under test during the test step may be accounted for either by exploiting the maximal voltage of the device under test provided by the user, or by accounting that for modern Li-Ion cells the voltage of a fully charged battery pack is approximately 25% higher than the voltage of a discharged battery pack. This allows computation of the required maximal current and maximal power for the next few minutes, and the prediction can then also be adapted during operation to provide better estimates and finer granularity.

Similarly, for a constant current-constant voltage (CCCV) charging step, the maximal current may be specified by the test plan and the maximal power may be computed by multiplying this by the specified final voltage to hold. Additionally, the current and required power both rapidly decrease after reaching the target voltage. The battery management system (BMS) of a battery pack may communicate with the test bench control system and change one or more test limits. However, the battery management system may only be allowed to reduce the maximum current or/and power insofar as the primary task of the battery management system is to protect the battery pack, and protection may be limited to derating (reducing) the maximal power (or current) that the battery pack can provide.

The priorities of the individual test benches and devices under test may be specified on a laboratory level by management software which communicates directly with the test bench control system. Alternatively, the priorities of the individual test bench control units may be specified by the operator of the individual test bench control unit. These priorities are then used in case that the maximum power of the power cluster is reached, to decide which test bench should be halted or paused first.

The power distributor (PD) may be responsible for splitting the instantaneous current setpoints from the individual control units (CU) among the allocated power units. The number of parts in which current is to be split may depend on the routing inside the power router at any one time. As such the power distributor operates under hard real-time requirements and may be required to meet a low latency threshold. The high-speed serial interface for communication is only an example of the communication topology. Alternatively, since the selected power units have a high internal impedance (current sources) and can balance the currents between several units, interfaces slower than a high-speed serial interface may be provided, such as interfaces based on Ethernet with sampling rates of up to 5 k/s.

The power distributor is responsible for activating a new unit, synchronizing the new unit to the voltage of the device under test with a command setpoint of 0 current, and then appropriately ramping up the current once there is a change in the routing topology and power units need to be added or removed to a channel.

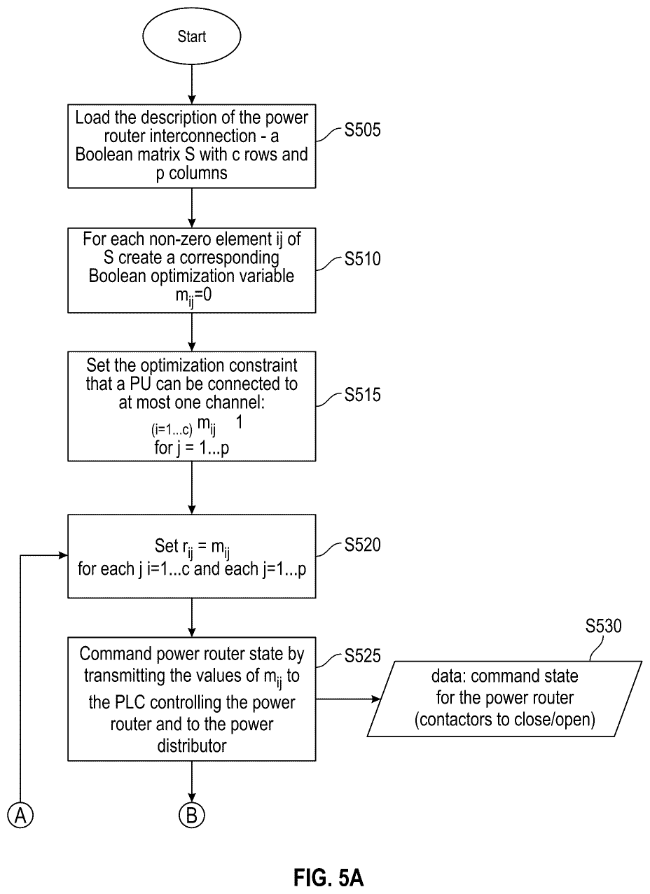

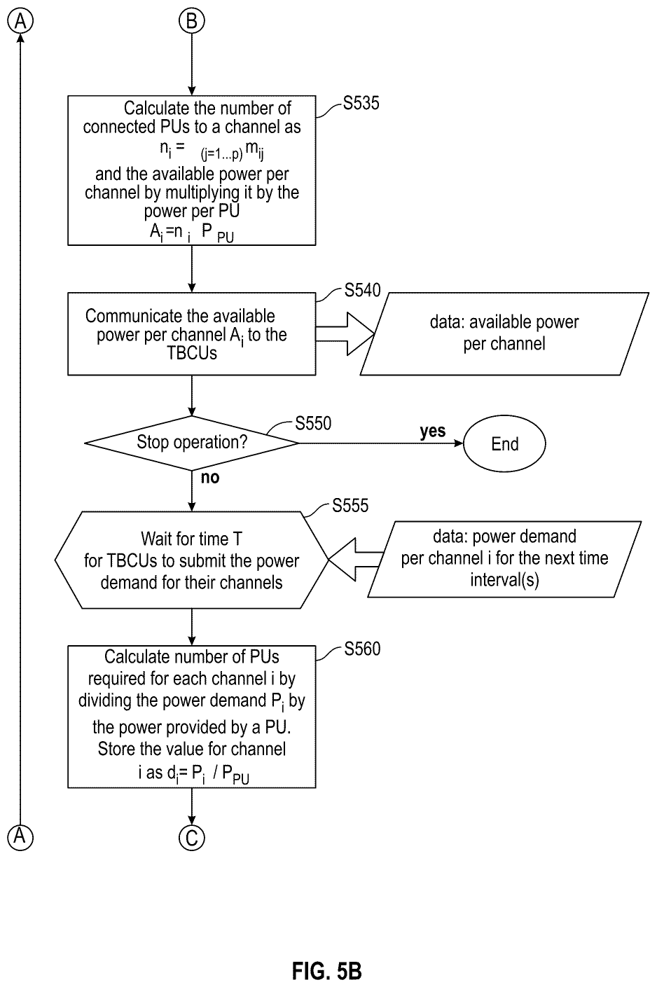

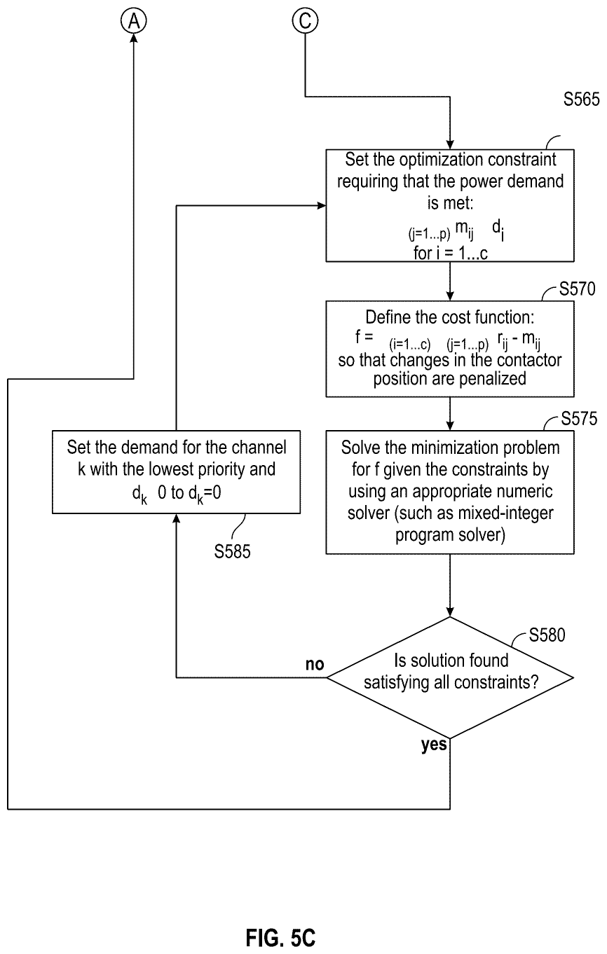

FIG. 5A, FIG. 5B and FIG. 5C are an illustrative view of a method for intelligent power allocation for high-power test laboratories, in accordance with a representative embodiment.

The method of FIG. 5A, FIG. 5B and FIG. 5C starts at S505 by loading a description of a power router interconnection as a Boolean matrix S with c rows and p columns.

At S510, for each non-zero element ij of the Boolean matrix S, a corresponding Boolean optimization variable mᵢⱼ is created.

At S515, an optimization constraint is set. The optimization constraint may specify that a power unit is to be connected to at most one channel as Σᵢ₌₁^{c}mᵢⱼ≤1, for each j=1 . . . p.

At S520, the reference value rᵢⱼ of each Boolean optimization variable is set to be equal to mᵢⱼ.

At S525, a power router state is commanded. The power router state may be commanded by transmitting the values of mᵢⱼ to the programmable logic controller controlling the power router and to the power distributor.

At S530, data is sent to the power router as data for a command state to indicate whether contactors should be closed or open.

At S535, a number of power units connected to a channel is calculated as nᵢ=Σⱼ₌₁^{p}mᵢⱼ, and the available power per channel is calculated as Aᵢ=nᵢP_{PU}. The number of power units n is calculated for each channel i as a function of the optimization variables for the channel. The power per channel Aᵢ is calculated by multiplying the number of power units n by the power per power unit P_{PU}.

Given a switch matrix topology (as described above in connection with FIG. 4A) and power demand for each channel calculated in S535, the task of the power allocation control is to identify the optimal configuration of switches in the power router, such that the power demand at the output is satisfied. The problem may be represented mathematically and solved as an integer programming optimization problem. To describe this problem mathematically, for each output channel, the number of power units that are needed may be determined based on the power demand in the channel and the power capabilities of a single power unit. The power demand per channel and the power capabilities of each individual power unit may be determined to achieve the desired power or to achieve the desired current, and in both cases the number of power units may be determined as a whole number (non-negative integer). For each power unit, only one contactor may be closed, as otherwise two channels may be shorted. The switch matrix topology may be represented as a c×p Boolean matrix S, where 0 means no connection, and 1 means contactor present. Each of the c rows represents one of the output channels, and each p column represents one of the power units. Notably, the positions of the rows and the columns may be permutated without changing the result, as this is equivalent to renaming the power units or the channels. Each column of the Boolean matrix S may have at least one “1”—as otherwise an input is not connected. Each row of the Boolean matrix S may have at most one “1”—as otherwise and two DUTs will be shorted together. The representation of a switch matrix provided by a Boolean matrix S may also be used in the event that a power unit is integrated into or dedicated to a test bench control unit, as the corresponding row may have only one “1”, as the safety contactor in the test bench control unit may be what is represented in the switch matrix.

At time k, the state of the switch matrix may be represented with a second c×p Boolean matrix M(k), with 0 meaning that a contactor is open, and 1 meaning that the contactor closed. The representation of the switch matrix provided by the Boolean matrix M(k) allows representing arbitrary connections.

The search for M(k) may be posed as an integer optimization program. If mᵢⱼ∈0,1 are the coefficients of M that need to be determined, the pairs (i-j) correspond to the non-zero positions of the Boolean matrix S (that is sᵢⱼ=1, and all other positions mᵢⱼ=0). If dᵢ∈W are the elements of the power demand vector D(k)∈W^{c}, and W is the set of whole numbers (non-negative integers), the following constraints may be imposed:
(i)—0≤mᵢⱼ≤1, for all m variables (that is, the i-j pairs, where sᵢⱼ=1)—the contactors are either closed or open→Boolean variables.
(ii)—Σᵢ₌₁^{c}mᵢⱼ≤1, for each column j=1 . . . p—that is, a power unit may be connected to at most one row, that is to at most one DUT channel.
(iii)—Σⱼ₌₁^{p}mᵢⱼ≥dᵢ, for each row i=1 . . . c—that is each channel should have at least as many connections, as needed to meet the power demand.

Solving for the two inequalities (ii) and (iii), multiple solutions may exist. To reduce the size of possible solutions, the following objective function may be added: minimize the number of changed switch positions, compared to the previous state of M(k−1). Let rᵢⱼ be the states of the variables at k−1. Then the cost function in S570 is

$$f = {\sum }_{i = 1}^{c} {\sum }_{j = 1}^{p} \vert {r}_{i j} - {m}_{i j} \vert$$

As an example, the optimization approach for the switch matrix may be implemented in Matlab using the intlinprog solver of Matlab. A solution for the Boolean matrix S with c=16, p=72 may be reliably found in approximately 0.3 seconds of computation time. As a result, power allocation control may be executed in a range, for example, of 10 to 300 seconds.

The description of the routing problem as integer programming problem may allow for adding priorities for the channels. Priorities for channels may be used in the event the power of the power cluster is not sufficient for all channels at the same time. Additional constraints may be added to account for prediction of the power demand for each test bench control unit.

At S540, the available power per channel Aᵢ is communicated to the test bench control units.

At S550, a determination is made whether to stop the operation. If the operation is to be stopped (S550=Yes), the operation is ended.

If the operation is not to be stopped (S550=No), the method of FIG. 5A, FIG. 5B and FIG. 5C waits for time T for the test bench control units to submit the power demand for their channels for the next time interval(s).

At S560, the number of power units required for each channel i is calculated by dividing the power demand Pᵢ by the power provided by a power unit. The value for the number of power units required for each channel is stored for each channel i as dᵢ=|Pᵢ|/P_{PU}.

At S565, an optimization constraint is set. The optimization constraint requires that the power demand is met by Σⱼ₌₁^{p}mᵢⱼ≥dᵢ.

At S570, the cost function is defined as f=Σᵢ₌₁^{c}Σⱼ₌₁^{p}|rᵢⱼ−mᵢⱼ|.

At S575, a minimization problem is solved for f given the constraints. An appropriate numeric solver is used to solve the minimization problem, such as an integer program solver.

At S580, a determination is made whether a solution has been found satisfying all constraints.

If a solution is not found at S580 (S580=No), the method of FIG. 5A, FIG. 5B and FIG. 5C sets the demand for a channel to 0 at S585 and then returns to S565.

If a solution is found at S580 (S580=Yes), the method of FIG. 5A, FIG. 5B and FIG. 5C returns to S520 and the new state of the switching matrix is recorded by setting rᵢⱼ to be equal to mᵢⱼ and the method from S520 to S585 is repeated.

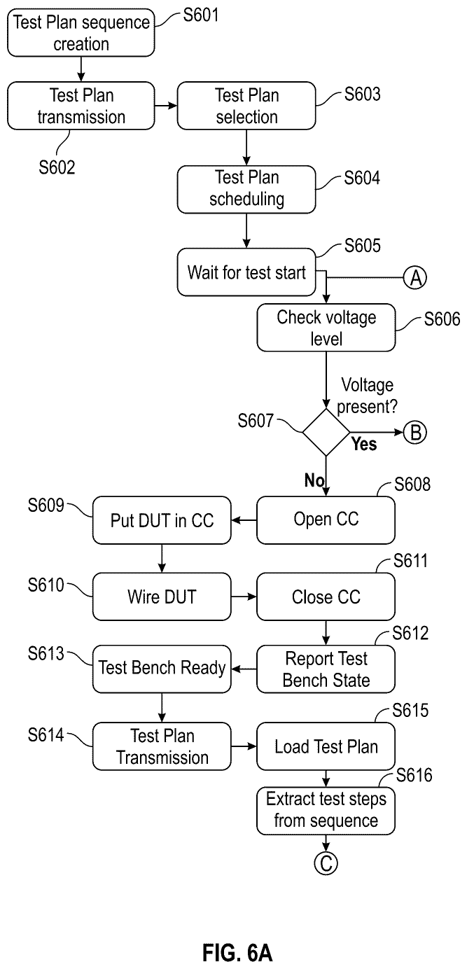

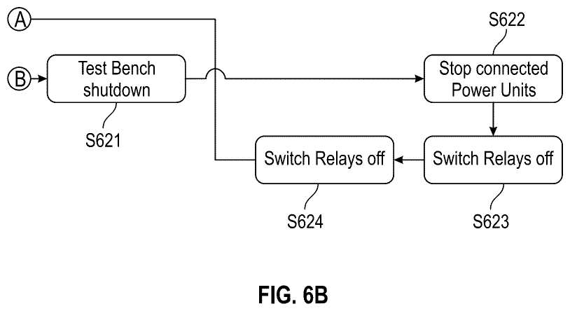

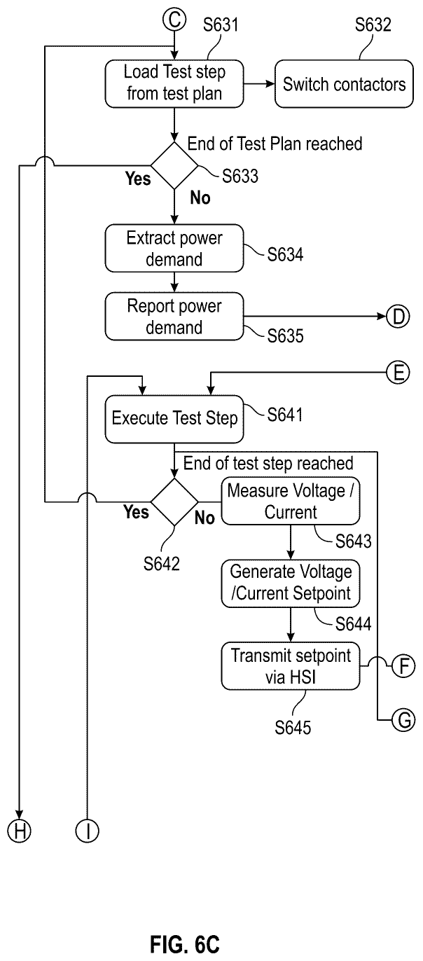

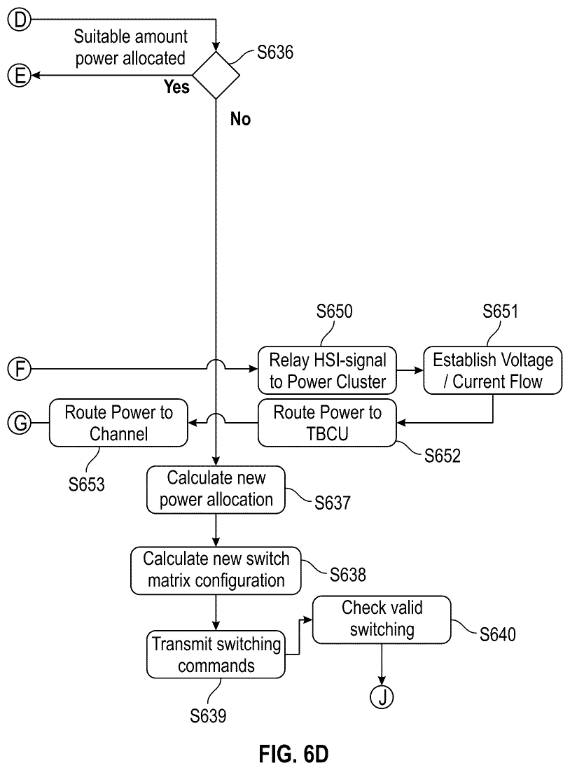

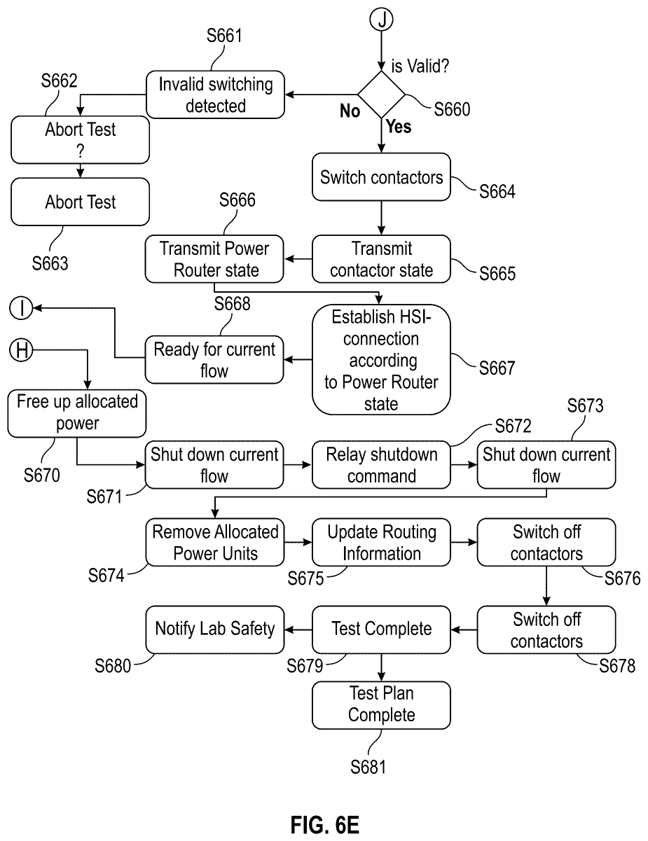

FIG. 6A, FIG. 6B, FIG. 6C, FIG. 6D and FIG. 6E are an illustrative view of a method for intelligent power allocation for high-power test laboratories, in accordance with a representative embodiment.

The method of FIG. 6A, FIG. 6B, FIG. 6C, FIG. 6D and FIG. 6E starts at S601 by creating a test plan sequence for each DUT.

At S602, the test plan is transmitted to a server (not shown), which may store the test plans for DUT

At S603, the test plan is selected for implementation.

At S604, the test plan is scheduled.

At S605, the method of FIG. 6A, FIG. 6B, FIG. 6C, FIG. 6D and FIG. 6E includes waiting for the test to start.

At S606, a voltage level is checked.

At S607, a determination is made as to whether a voltage is present.

If no voltage is present (S607=No), at S608 the climate chamber is opened, and at S609 the device under test is put in the climate chamber.

At S610, the device under test is wired, and at S611 the climate chamber is closed.

At S612 the test bench state is reported, and at S613 the test bench is determined to be ready.

At S614, the test plan is transmitted to the corresponding TBCU, and at S615, the test plan is loaded in the TBCS of the TBCU.

At S616, test steps are extracted from the sequence in the test plan.

If voltage is present at S607 (S607=Yes), the test bench is shut down at S621. The power cluster is commanded to stop the connected power units at S622, and relays are switched off at the power router at S623 and at the test bench control unit at S624 so that the method returns to S607.

After S616, a test step is loaded from the test plan at S631. Contactor(s) inside the TBCU are also switched at S632 based on loading the test step at S631.

At S633, a determination is made as to whether the end of the test plan is reached.

If the end of the test plan is not reached (S633=No), power demand is extracted at S634 and reported to the power allocation manager at S635.

A determination is made at S636 whether a suitable amount of power is currently allocated, and if so (S636=Yes), the test step loaded at S631 is executed at S641.

Another determination is made at S641 whether the end of the test step is reached, and when the end of the test step is reached (S642=Yes), the method returns to S631 to load another test step from the test plan.

When the end of the test step is not reached at S642 (S642=No), at S643 the voltage and the current for the channel are measured at the TBCU, at S644 the voltage/current setpoint is generated inside the control unit of the TBCU, and at S645 the setpoint is transmitted via a high-speed interface (HSI) to the power distributor of the power allocation manager.

At S650, the HSI signal is relayed to corresponding power unit inside the power cluster, and at S651 the PU establishes the commanded setpoint of voltage or current. At S652, power is routed to the test bench control unit over the closed contacts inside the switch box of the power router, and at S653 power is routed over the TBCU to the specific channel being tested, after which the method returns to S642.

If a suitable amount of power is not allocated by the power allocation controller of the power allocation manager at S636 (S636=No), a new power allocation is calculated at S637 and a new switch matrix configuration is calculated at S638. Switching commands are transmitted to the power router at S639, and at S640 a check is made by the programmable logic controller of the power router as to whether the switching is valid.

A determination is made at S660 as to whether the switching is valid. If the switching is not valid (S660=No), invalid switching is detected at S661, a determination is made by the TBCS whether to abort the test at S662, and the test is aborted at S663.

If the switching is valid (S660=Yes), contactors are switched at S664, the contactor state is transmitted back to the power allocation controller inside the power allocation manager at S665, and the power router state is transmitted to the power distributor at S666. At S667, a HSI connection is established according to the power router state. At S668, the HSI connection is ready for current flow and the method returns to S641 to execute the test step.

When the end of the test plan is reached (S633=Yes), at S670 the test bench control system frees the allocated power and at S671 the control unit shuts down the current flow from the test. At S672, a relay shutdown command is relayed and at S673 the current flow is shut down based on the shutdown command.

At S674, power units allocated for the test by the power allocation manager are removed from the test and made available for other tests. At S675, routing information is updated. At S676, contactors are switched off.

At S679, the test is deemed complete at the test bench control system and at S680 the lab safety monitor is notified.

At S681, the method of FIG. 6A, FIG. 6B, FIG. 6C, FIG. 6D and FIG. 6E is complete.

In the method of FIG. 6A, FIG. 6B, FIG. 6C, FIG. 6D and FIG. 6E, power from the plurality of power units is dynamically allocated to a plurality of test bench control units, such as a first test bench control unit and a second test bench control unit, based on test plans for the first device under test and the second device under test and based on requests from the plurality of test bench control units.

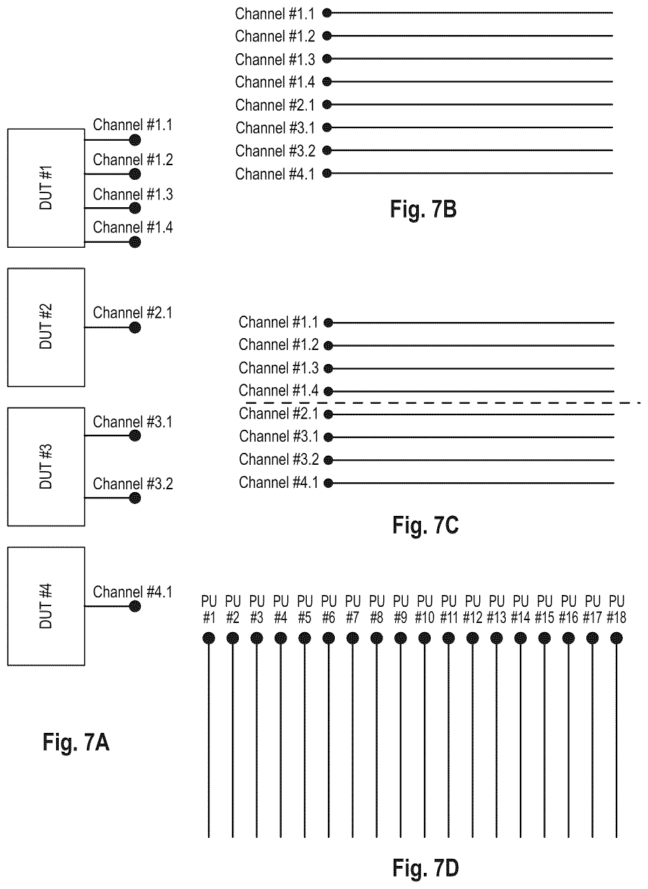

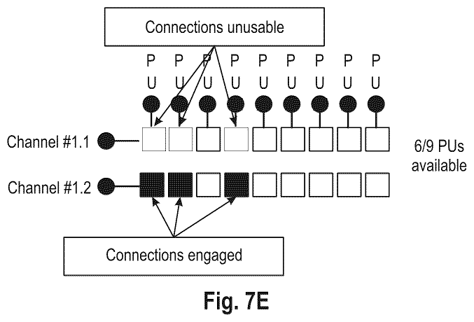

FIGS. 7A-7E show a workflow for determining a switch matrix used to connect power units selectively to DUT's using rows and columns of switches. Various aspects and details of the representative embodiments described above in connection with FIGS. 1-6E, including allocation of power and switching, may be common to the presently described representative embodiments. These common aspects and details may not be repeated in order to avoid obscuring the presently described representative embodiments.

FIG. 7A show an assignment of DUT's to channels of a battery pack test system in accordance with a representative embodiment. In the present example, a first DUT 702 is connected to channels 1.1, 1.2, 1.3 and 1.4. A second DUT 704 is connected to channel 2.1; a third DUT 706 is connected to channels 3.1, and 3.2; and a fourth DUT 708 is connected to channel 4.1.

As will become clearer as the present description continues, the channels connected to the first-fourth DUT's 702˜708 are connected to rows in a block of switches forming a switch matrix to provide the required average and peak electrical power to each DUT. Specifically, as shown in FIG. 7B, channels 1.1, 1.2, 1.3, 1.4, 2.1, 3.1, 3.2 and 4.1 are arranged in rows corresponding the rows of the blocks of switches that form the switch matrix of various representative embodiments.

As will also become clearer as the present description continues, each row of the switch matrix is connected to a DUT, and the number of rows (and therefore the number of channels) of each block of the switch matrix is limited to a predetermined number. As described more fully herein, the number of rows of each block of the switch matrix is governed by the number of channels connected to a particular DUT. The number of rows of each block is set. Beneficially, the channels are grouped by evaluating DUT's with similar requirements and physical proximity. In a representative embodiment shown in FIG. 7C, there are illustratively four channels in each block. As such, the switch matrix generally comprises a plurality of blocks where each block has four connections, and therefore can connect a power unit to one of the DUTs. Furthermore, the total number of rows in the switch matrix comprised of the blocks of switches is equal to the total number of channels required for testing the DUT's in a battery test.

Next, the number of columns of the switching matrix are determined. As shown in FIG. 7D, each column is connected to one power unit. As described more fully herein, switches of the switch matrix comprising blocks of switches are selectively engaged to connect the power units to the channels of the DUT's and thus to the DUT's for testing. The number of channels dictates the number of power units available for testing, where the number of power units needed is based on the sum of average power demands for each channel. Notably, the average power for each channel also factors the peak power for each DUT. Specifically, in accordance with a representative embodiment, peak power demands are provided by the user, along with a factor of the duration of the peak power required of a DUT and the duration of the time when the DUT is drawing no power. These data are used to determine the average power for each DUT, and the number of power units are determined. In this way, each DUT is analyzed and the determined average power is used to determine the total number of power units (and thus the number of columns).

Notably, the techniques of various representative embodiments enable the determination of the total numbers of rows and columns for the required switch matrix. Overlaying FIG. 7C and FIG. 7D results in the total switch matrix with intersecting rows and columns. These intersections represent possible connections between the respective PU and the respective channel (and thus DUT). One approach is to physically realize every connection by introduction a switch at each of these intersections. To save on hardware and complexity, the various representative embodiments enable the determining of the minimum number of physical connections needed for each channel. The peak power requirements of each channel represent the largest magnitude of power each channel requires. As such, in accordance with representative embodiments, to meet the power demand, the system is adapted to provide at least the number of required connections from PUs to the respective channels, so that the summed power of the respective PUs is equal or greater than the peak power. The peak power requirements of each DUT is also used to determine the number of power units needed to meet the demand of each DUT. Specifically, the number of connections to the power units needed to meet these peak requirements is determined.

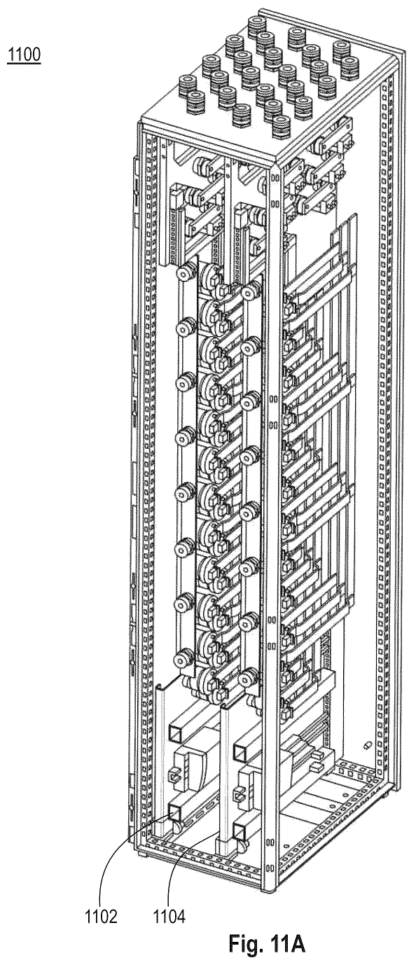

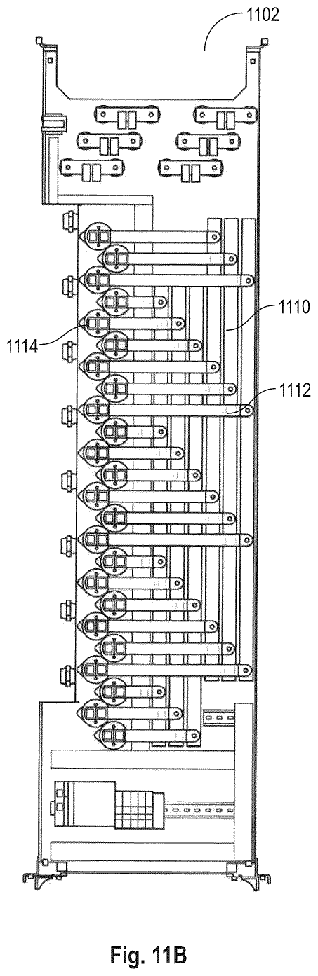

Once the requirements of each DUT channel is determined, the number of power units per channel connected to the DUT is known, in a block-wise manner, the switches are selectively engaged to power each DUT. In accordance with a representative embodiment, the blocks of switches are illustratively 4×6 or 4×3 switches. In this illustrative example, the capabilities of the mounting plates and power routers (described above) set the size of each of the mounting blocks. As described more fully below, in various representative embodiments, each mounting plate comprises three power units and connections for four channels. Furthermore, in an illustrative example, the power routers described above can connect to four channels. As such, blocks of switches having four rows and three columns are used to effect the connections between the power units and the DUT's to meet the power requirements of each DUT. Moreover, and again as described below in connection with FIGS. 11A-13, two mounting plates may be provided in each module, thereby a 4×6 block of switches can be used to engage selectively the required number of power units. It is emphasized that blocks of 4×3 and 4×6 switches adapted to connect channels (rows) of a DUT selectively with the required number of power units to meet the average and peak power requirements of the DUT are provided merely for the purposes of illustration, and are not intended to be limiting. For example, the number of rows and columns may be based on the electronic capabilities of the mounting plates and the number of power units that the power routers can connect. More generally, more or few rows (connections to channels of a DUT), and more or fewer columns (connections to power units) comprising the blocks of switches are contemplated. For example, blocks of 3×6 or 6×8 are contemplated. It is emphasized however, that the use of 4×3, 4×6, 3×6 or 6×8 blocks of switches is merely illustrative, and other size blocks of switches within the purview of the ordinarily skilled artisan having the benefit of the present teachings are contemplated.

Just by way of illustration, in the example shown in FIG. 7D, the sum of the power units needed to provide the required power is 18, comprising 6 groups of 3 power units connecting to one mounting plate. Illustratively, the power units are provided in groups of three, and the DUT-channels are provided in groups of four. The resulting blocks of switches is thus 4×3. Moreover, the illustrative 18 power units are provided in six groups of three power units. Next, the number of power units needed to meet the peak demand for each channel is determined. Just by way of illustration, channels 1-1.4 may be determined to need nine power units each, and channels 2.1-4.1 may each require six power units each.

Additional power units may be used to provide a redundancy. In practice it may be useful to provide more than the predetermined number of connections in the matrix, because all connectable power units may not be available. In this case, when a power unit is connected to another DUT the peak power of a DUT may not be able to be provided. For example, FIG. 7E two rows of a block matrix comprising nine columns, providing a 2×9 block of switches. The filled squares indicate switches that are engaged, and the empty squares indicate switches that can be engaged to connect a power unit to a channel. Notably, there are three grayed out squares shown. These grayed out squares indicate locations in the switch matrix that are not available to be engaged, and thus are not usable. Specifically, the power requirements of each DUT is used to select the number of power units required. Once engaged, therefore, a power unit is dedicated or reserved for a particular DUT to meet its calculated peak and average power requirements. As such, a power unit engaged by a particular DUT cannot be engaged to provide power to another DUT in order to avoid not being able to meet the power requirements of the particular DUT. So, in the illustrative example, power units 1, 2 and 3 have been engaged to meet the power requirements of channel 1.2. These power units are therefore not available to provide power to channel 1.1, and connections to the remaining six power units can be made to meet the demands of the DUT connected to channel 1.1 However, the remaining six of nine power units available to provide power by selection of available switches in the top row may not be sufficient to meet the power demands of channel 1.1. To avoid not being able to provide enough power to a DUT connected to channel 1.1 in FIG. 7E, connections to other power units are provided via redundancy in a manner described more fully below. Notably, this way the specific power demands of each channel of the DUTs can be achieved. Moreover, and as described more fully below, none of the power units can be connected to more than one column to avoid, among other things, the possibility of shorting two DUT's, which can cause damage to the DUT's, or danger, or both.

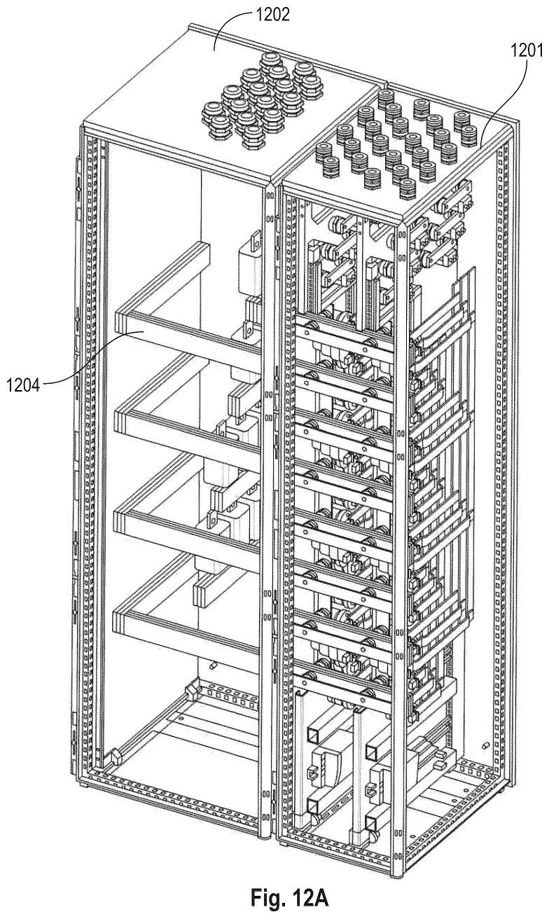

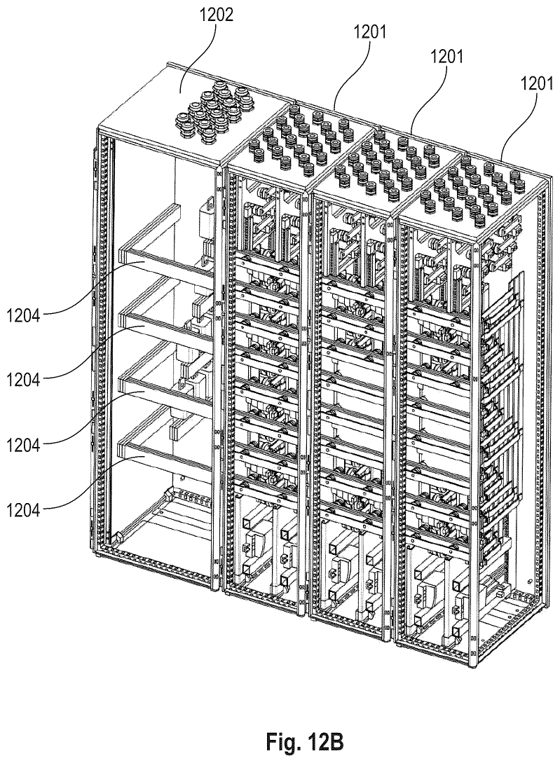

While redundancy is useful to ensure meet the requirements of peak power and average power for each DUT, this must be weighed against the cost and complexity the redundancy requires. Specifically, and as described in connections with FIGS. 11A-12B, each block of switches and the necessary connections to connect each DUT come at a cost. The more switches and connections that are provided to the DUT's in a particular application the higher is the cost. As such, in accordance with the present teachings, the desired redundancy is optimized so that sufficient power requirements of the DUT's are met, without provided an excessive number of switches and their attendant connections to the DUT's. This is done by the careful determination of the average and peak power requirements of each of the DUT's as described herein.

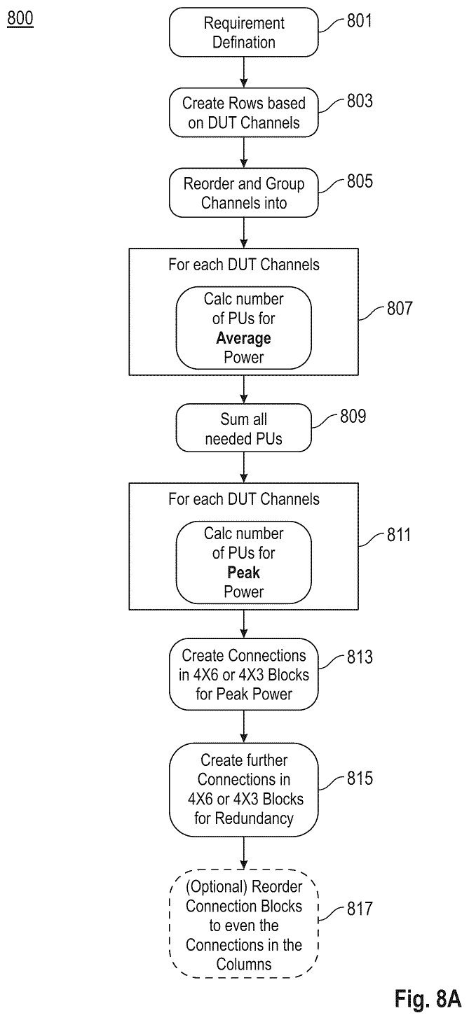

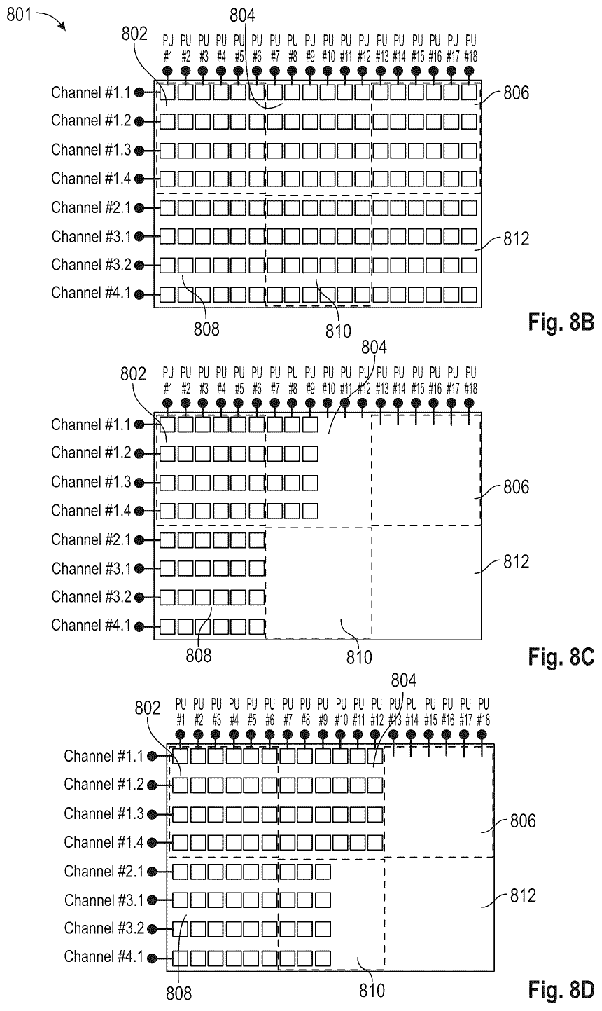

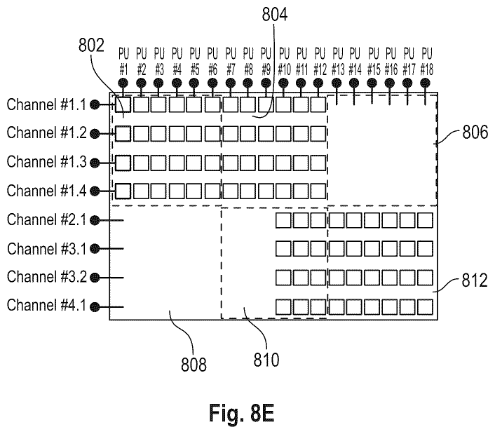

FIG. 8A is a simplified flow diagram of a method 800 of selecting blocks of switches to form a switch matrix for testing a battery pack in accordance with a representative embodiment. Various aspects and details of the method 700 are common to those described in connection with the various representative embodiments of FIGS. 1-7E. These common aspects and details may not be repeated to avoid obscuring the presently described representative embodiments.

At 801, the method begins with the determination of the requirements of the DUTs to be tested by a battery pack test system of a representative embodiment. In accordance with a representative embodiment, this determination of the requirements of the DUTs can be done by analyzing test procedures from the user with regards to average and peak power, while accounting for keeping down-times, service, and other times when no power is necessary. This could also be based on information about simultaneity factors of DUT usage and DUT characteristics.

At 803, the method 800 comprises creating the number of rows of the switch matrix based on the number of channels required of the DUT's. As described above, each channel is connected to a row of the switch matrix, and each switch matrix comprises blocks of switches comprising a predetermined number of rows. At 805, reordering of the rows is carried out and the rows are grouped in the predetermined number of rows. In accordance with a representative embodiment, this is done based on the selected size of the blocks of switches. Though it is possible to use blocks of switches of different sizes (different numbers of rows and columns), by using only one size only one type of hardware is needed. For example, when choosing blocks with four rows, those four connections for channels will be physically present at the hardware. Thus, it is possible for the number of rows to differ from the number of channels. Therefore, it is more cost-effective the less rows are unused. As such, and in keeping with the above-described representative embodiments, there are four rows in each block of switches.

At 807, for each DUT, the average power requirement is determined. As noted above, this is based on input from the user. Once the average power requirement for each DUT is determined, the average power requirement is determined for each channel is known, and the number of power units required to meet the average power demands of each DUT is determined.

At 809, the total number of power units is determined based on the power requirements of each DUT determined at 807.

At 811, for each DUT, the peak power requirement is determined. As noted above, this is based on input from the user. Once the peak power requirement for each DUT is determined, the peak power requirement is determined for each channel is known, and the number of power units required to meet the peak power demands of each DUT is determined.

At 813, blocks of switches are created to provide the connections between the various power units and the channels of the DUTs. These blocks of switches thus form the switch matrix used to power the DUT's based on their peak and average power requirements. As noted above, in certain representative embodiments, these blocks of switches comprise four rows (for connecting four channels) and three columns (for connecting three power units) or 4×3 blocks of switches, or four rows (for connecting four channels) and six columns (for connecting six power units) or 4×6 blocks of switches. Again, as described more fully below, in a representative embodiment, each mounting plate comprises three power units and connections for four channels. So, each mounting plate requires a block of switches of 4 rows and 3 channels. Moreover, two mounting plates may be provided in each module, thereby a 4×6 block of switches can be used to engage selectively the required number of power units. It is emphasized that blocks of 4×3 and 4×6 switches adapted to connect channels (rows) of a DUT selectively with the required number of power units to meet the average and peak power requirements of the DUT are provided merely for the purposes of illustration, and are not intended to be limiting. Rather, and as described more fully below, more or few rows (connections to channels of a DUT), and more or fewer columns (connections to power units) comprising the blocks of switches are contemplated.

At 815 the method 800 continues by creating further blocks of switches to provide a redundancy in order to meet the power requirements of the DUTs should the power units determined at 809. As described below, this redundancy may be carried out by providing more blocks of switches determined at 813, and thus providing a switch matrix that is filled more than the number of switches determined at 813. It is noted this level of redundancy is merely illustrative and greater or lesser redundancy is contemplated.

At 817, the method continues with the optional step of reordering the blocks of switches to even the number of connections in the columns, and thus to the power units. As shown and described in connection with FIG. 8D below, this may be done so the number of connections in each column is equal to the extent possible. This reordering distributes the connections for each of the power units as much as possible.

FIG. 8B is a simplified schematic view a switch matrix comprising six blocks of switches available to connect power units to DUT's in accordance with a representative embodiment. Various aspects and details of the representative embodiments described above in connection with FIGS. 1-7E, including allocation of power and switching, may be common to the presently described representative embodiments. These common aspects and details may not be repeated in order to avoid obscuring the presently described representative embodiments.

Turning to FIG. 8B, a switch matrix 801 comprising six block of switches is shown. Specifically, the switch matrix 801 comprises a first block of switches 802, a second block of switches 804, a third block of switches 806, a fourth block of switches 808, a fifth block of switches 810 and a sixth block of switches 812. Notably, as shown, each switch block comprises four rows and six columns (4×6). As described above, the number of rows is determined based on the number of channels of the DUT's and the number of columns is determined based on the number of power units needed to meet the peak and average power requirements of each DUT connected to the respective rows.

FIG. 8C shows switch matrix 801 after the determination of the number of power units is completed based on the average and peak power requirements of the DUT's. In this illustrative example, based on the number of channels of the DUT's and the power requirements of the DUT's, the first block of switches 802 is a 4×6 block, the second block of switches 804 is a 4×3 block, the fourth block of switches 808 is a 4×6 block. Notably, based on the power requirements of the DUT's, the third block of switches 806, the fifth block of switches 810 and the sixth block of switches 812 are not connected in this arrangement.

FIG. 8D shows switch matrix 801 after the determination of the number of power units is completed based on the average and peak power requirements of the DUT's and includes redundancy so that twice the number of switches are provided and thereby the number of power units that can be accessed to ensure power requirements (especially at peak power) can be met. In this illustrative example, based on the number of channels of the DUT's and the power requirements of the DUT's, the first block of switches 802 is a 4×6 block, the second block of switches 804 is a 4×6 block, the fourth block of switches 808 is a 4×6 block and the fifth block of switches 810 is a 4×3. Notably, the third block of switches 806 and the sixth block of switches 812 are not connected in this arrangement.

FIG. 8E is a simplified schematic view a switch matrix comprising three blocks of switches available to connect power units to DUT's in accordance with a representative embodiment. FIG. 8E improves the distribution of power among otherwise unused power units to more efficiently use all available power units to meet the power requirements of each DUT. Specifically, in the switch matrix shown in FIG. 8D, the last six power units (PU #13-PU #18 in this example) are not being used. To better distribute the connections and to some extent avoid overloading the first twelve power units (PU #1-PU #12) while some power units are not in use, connections are distributed to connect as many power units available for connection. And in this example, here, this objective is achieved by “shifting” the bottom blocks in the fourth and fifth blocks of switches to the right, and nearly have an equal amount of connections for each power units. In the example shown, by making this change, only the tenth-twelfth power units (PU #10-PU #12 in this example) have connections to two blocks of switches, which in this example is twice the number of connections as the remaining fifteen power units.

As will be appreciated, and as discussed more fully below in connection with FIGS. 11A-12B, the forming of the switch matrix shown in FIG. 8E is readily effected using mounting plates having 4×3 connection capabilities of the illustrative examples described herein.

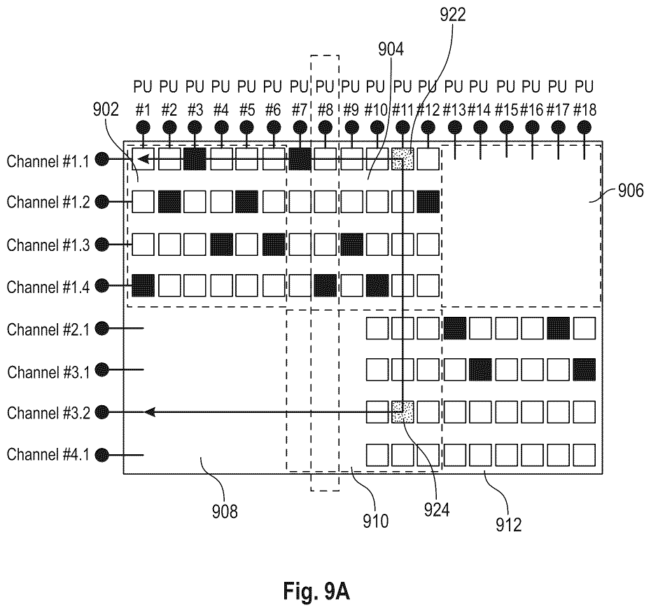

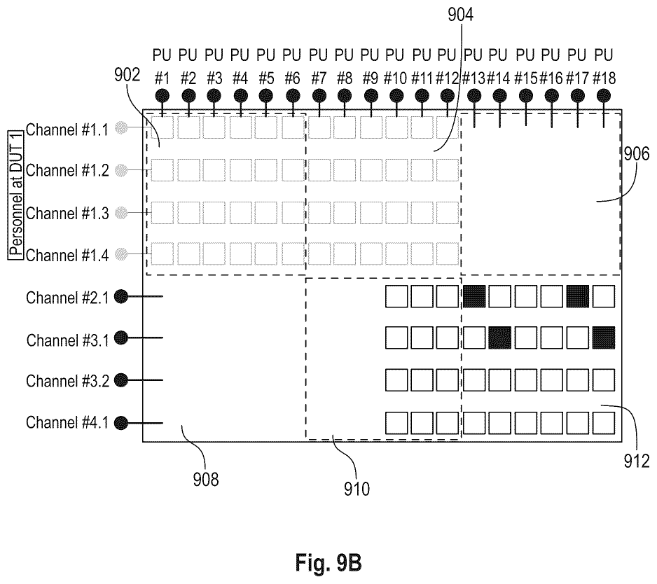

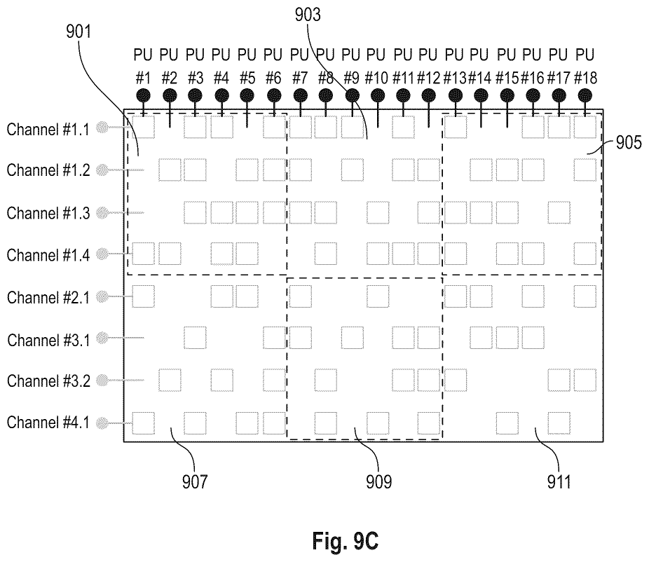

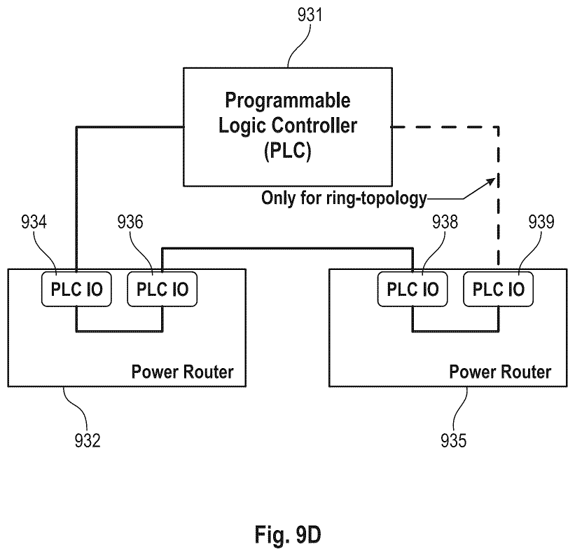

FIG. 9A is a simplified schematic view of the switch matrix of FIG. 8E having an improper connection of one power unit to two DUTs. Various aspects and details of the representative embodiments described above in connection with FIGS. 1-8E, including allocation of power and switching, may be common to the presently described representative embodiments. These common aspects and details may not be repeated in order to avoid obscuring the presently described representative embodiments.

Turning to FIG. 9A, the switch matrix 900 has first-sixth blocks of switches 902˜912 in which engaged switches are shown in black/filled squares and available switches are blank.

As noted above, only one switch in each column should be engaged at a time. In the present example, switches 922 and 924 are shaded to illustrate a potentially dangerous connection. Specifically, if switches 922 and 924 were both engaged at the same time, channels 1.1 and 3.2 would be connected, and DUT's 1 and 3 (as shown in FIG. 7A) would be connected. This connection results in a shorting of DUT's 1 and 3, and could result in damage to the DUT's, or a dangerous electrical issue, or both. Accordingly, in accordance with a representative embodiment, connections of the same power unit (in this case PU #11) and thus two connections in the same column should be avoided.

FIGS. 9B-9C are simplified schematic views is a simplified schematic view of the switch matrix of FIG. 8C having certain connections disabled for reasons of safety. Various aspects and details of the representative embodiments described above in connection with FIGS. 1-9A, including allocation of power and switching, may be common to the presently described representative embodiments. These common aspects and details may not be repeated in order to avoid obscuring the presently described representative embodiments.

FIG. 9B is a simplified schematic view of the switch matrix of FIG. 8C in which connections to one DUT disabled during service of the one DUT in accordance with a representative embodiment. and details of the representative embodiments described above in connection with FIGS. 1-9A, including allocation of power and switching, may be common to the presently described representative embodiments. These common aspects and details may not be repeated in order to avoid obscuring the presently described representative embodiments.

Turning to FIG. 9B, a situation in which disconnection of the first DUT is done, for example to remove and replace the DUT with another DUT for testing or similar reason. In this case, the connections of the first and second blocks of switches 902, 904 are disabled so no connections between power units (PU #1-PU #12) previously connected to the first DUT can be made.

In accordance with a representative embodiments, due to the safety relevance of correct disconnection, disabling of switches is done in two ways. A certified safety controller disconnects the physical connection of the switch and prevents this connection from being reactivated within the safety software. In addition, the safety controller removes the internal power from the switch so that even if a faulty signal commands the switch to activate the connection, the switch has no power to activate the connection and therefore does not establish the connection. Special switches may also be used to provide an auxiliary contact to monitor the actual state of the switch.

FIG. 9C is a simplified schematic view of switch matrix having an all connections all DUTs disabled during an emergent situation in accordance with a representative embodiment. In this case, the connections of the first-sixth blocks of switches 901˜911 are disabled so no connections between any of the power units (PU #1-PU #18) can be made.

FIG. 9D is a simplified schematic block diagram of a PLC 931 adapted to enable and disable switches for safety purposes. Various aspects and details of the representative embodiments described above in connection with FIGS. 1-9C, including allocation of power and switching, may be common to the presently described representative embodiments. These common aspects and details may not be repeated in order to avoid obscuring the presently described representative embodiments.

As shown, a first power router 932 comprises a first PLC input/output 934 and a second PLC input/output 936. Similarly, a second power router 935 comprises a first PLC input/output 928 and a second power router input/output 930. Illustratively, the power routers are located below the switches and rails shown in FIG. 11B The connections are provided on the roof of the cabinet in FIG. 11A and connected for each mounting plate.

As will be appreciated, the number of available switches (empty boxes in the blocks of switching of the switching matrix) is too large for a technician to enable/disable switches. Accordingly, instructions stored in memory executed by the PLC 931 will cause the PLC to identify connections that can result in potentially dangerous situations during testing of the DUT's. Notably, in accordance with a representative embodiment, the algorithm for engaging the power routers to disable/enable switches is described in connection with the representative embodiments of FIG. 6D, for example. Specifically, steps S638, S639, and S640 described above are carried out. A new configuration is calculated to determine which switches are to be connected. This configuration is sent from the PAM to the PLC (check FIG. 4B), the PLC checks this configuration and executes the switching.

As described above, during operation, it is important that the system does not engage an unsafe operating condition, wherein “unsafe” means unsafe to equipment and the health of the personnel working on the system.

Instead of the unit that creates the switching requests also executing them at the switches, a monitoring unit is needed here. To comply with the safety requirements, we implement the PLC 931. The PLC monitors the actual switching states, receives new switching requests, checks them for compliance, and executes them if permissible. Therefore, the PLC 931 connects to each Power Router and its internal PLC Ios. The topology is here only dependent on the PLC-technology used and supports line, ring, or other topologies. Providing safety for both the people working with the system, the system and the DUT's can be effected by the following rules, which were alluded to above.

First, connections between DUT channels must be avoided when DUT channels are connected to each other. These shorts can be between channels connected to the same DUT, or channels connected to different DUT's. This could cause a short circuit with unacceptable current flow that could result in catastrophe.

Second, specific connections must be avoided when personnel are handling a DUT: Personnel regularly must work with the DUT. This should be doable while other DUTs get powered. An incorrect established connection to a DUT where personnel is working on endangers these personnel.

Third, all connections must be terminated in case of emergency. For example in case of fire, flooding, or other emergency situations, it must be possible to terminate all connections. It seems to be very hard for the controller to check all these rules especially if you look at the matrix where all engaged connections are marked with black squares. Especially checking if DUT channels are connected to one another seems hard to oversee. The brute force approach would be checking each pair of channels and search for connections. This cannot be done practically by human hands due to the large number of switches that comprise the switch matrix.

To realize these safe conditions, the following rules are used. These rules are captured in instructions to be executed by the PLC to effect safe operations when the above three situations may occur.

First, and as noted above, only allow one established connection in each column. As described above, if multiple connections are established in a single column of the switching matrix, each corresponding channel (and in some cases DUT's) is connected together. This shorting must be avoided.

Second, and as noted above, only allow one established connection in each column. As described above, when a DUT is being serviced (e.g., a new DUT is added and a tested DUT is removed), the PLC locks all connections in a row(s) if personnel are handling a DUT. When personnel are handling the DUT all connections in that row are not allowed. Other channels can remain connected.

Third, and as noted above, in an emergency situation, the PLC locks all connections in a all rows of the switch matrix.

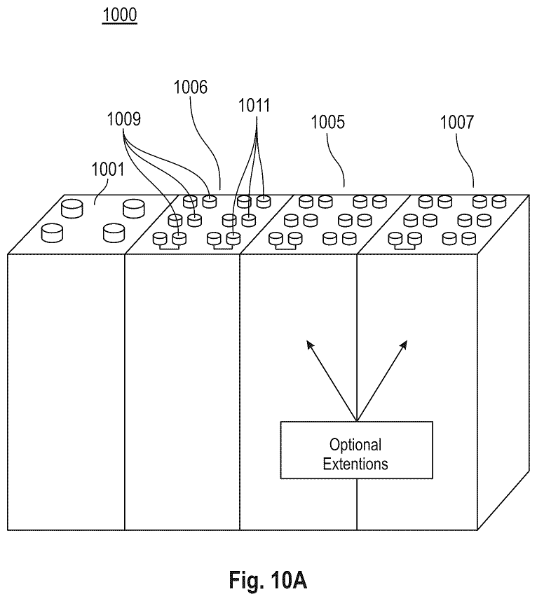

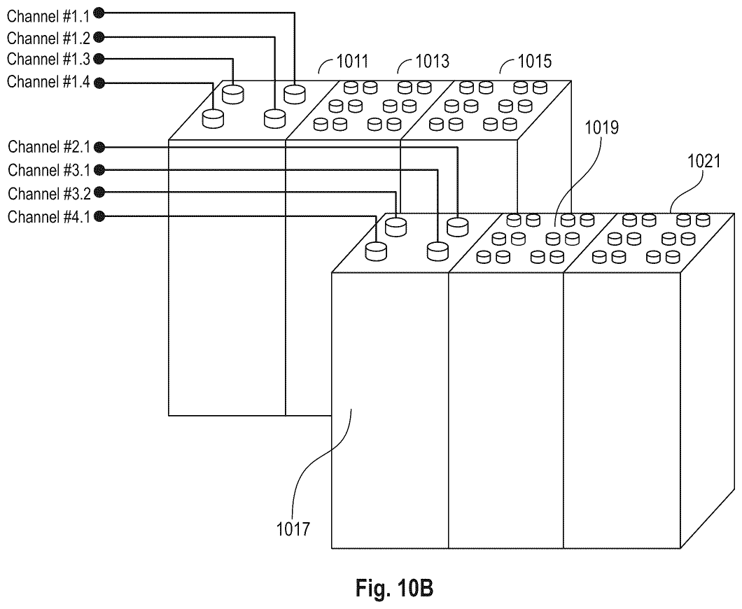

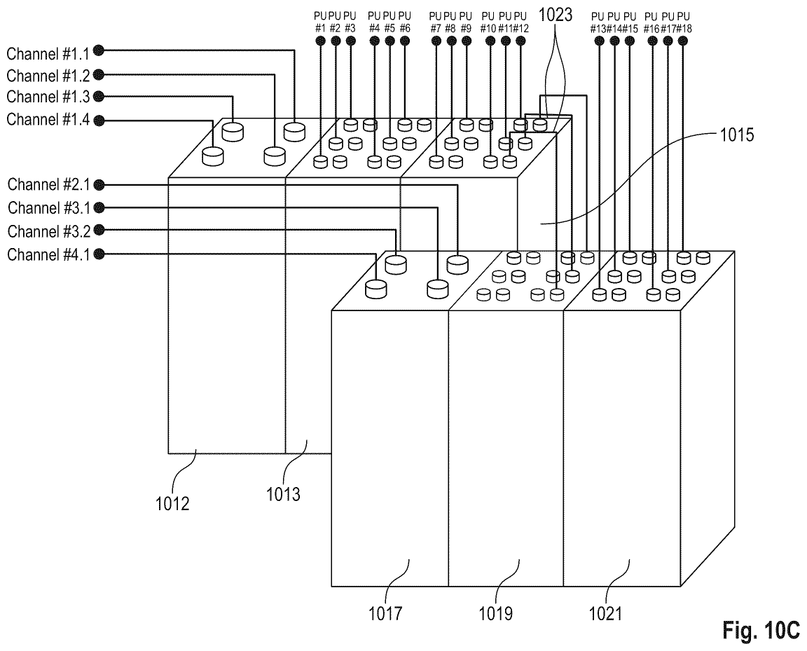

FIG. 10A is a simplified schematic view of a power router 1000 comprising a connection module 1001 connected to a first switch module (S module) 1003 and optional second and third S modules 1005, 1007 in accordance with a representative embodiment. Various aspects and details of the representative embodiments described above in connection with FIGS. 1-9C, including allocation of power and switching, may be common to the presently described representative embodiments. These common aspects and details may not be repeated in order to avoid obscuring the presently described representative embodiments.

In accordance with a representative embodiment, the power router hardware is built out of a connection module adapted to provide power to four DUT channels and switching cabinets each fitting two (or more) mounting plates (sometimes referred to as switching benches). With each mounting providing three inputs. Turning to FIG. 10A, the first S-module 1003 comprises two mounting plates, each providing a 4×3 block of switches for the resultant switch matrix resulting in the 4×6 blocks of switches, as described more fully above. Alternatively, in the case where only a 4×3 block is required (e.g., block of switches 804 of FIG. 8C) omitting one of the 4×3 blocks of switches provides the resultant 4×3 block of switches. Each connection of this block is realized inside the cabinet housing the power router 100 by the included switches. The inputs and outputs are provided by contacts on the roof to connect the power router to the power units and the DUT channels.

As shown in FIG. 10A, first-third switching modules 1006, 1005, 1007 are used to provide a particular switching matrix comprised of blocks of switches. Constructing the matrix means connecting the hardware in the right way so that the connections are made to effect the desired connections in the resultant switch matrix. Modular extension to realize the desired switch matrix comprised of blocks of switches is realized through connections between the connection module 1001 that provides the connections to the power units and the switching modules, and through connections between the switching module, where, in keeping with the above-described arrangements, each switching module illustratively comprises two switching (with 2 switching benches) that each provide a 4×3 block of switches in the switching matrix. This enables extension of the switch matrix by connection of S modules to increase the number of blocks of switches per group of each row.

As shown in FIG. 10A, connections are made using first and second feed-through-contacts 1009 and 1011. Each input that can be connected to a power unit is internally bridged with a feed-through-contact. This can be used to realize a branching of the load lines of the power units. If another power router is connected to this contact, the power units may also be connected to the additional power router. As will be appreciated, these connections of S modules are used to establish the connections in each column in a block of switches that is not inside the particular block of switches (e.g., shown as blank squares in FIGS. 8B-8E). However, and as noted above, coordination between the power pouters is necessary here since the power units cannot be connected to more than one DUT at the same time.

FIG. 10B is a simplified schematic view of first and second power modules connected to respective first switch modules (S modules) and optional S modules in accordance with a representative embodiment. Various aspects and details of the representative embodiments described above in connection with FIGS. 1-10A, including allocation of power and switching, may be common to the presently described representative embodiments. These common aspects and details may not be repeated in order to avoid obscuring the presently described representative embodiments.

As shown in FIG. 10B, a first C module 1012 connects channels 1.1, 1.2, 1.3 and 1.4 to a first S module 1013 and a second S module 1015, thereby providing connections to two 4×6 blocks of switches. Similarly, channels 2.1, 3.1, 3.2 and 4.1 are connected via a second C module 1017 to a third S module 1019 and a fourth S module, thereby providing connections to two additional 4×6 blocks of switches. In accordance with a representative embodiment, the illustrated setup of power routers resembles the previously created switch matrix in FIG. 8D and FIG. 8E. With two blocks of 4×6 switches for each of the four described channels there are enough switches to physically realize the connections from the switch matrix with redundancy (introduced in FIG. 8D).

FIG. 10C is a simplified schematic view of first and second connection modules (C modules) connected to respective first switch modules (S modules) and optional S modules in accordance with a representative embodiment. Various aspects and details of the representative embodiments described above in connection with FIGS. 1-10B, including allocation of power and switching, may be common to the presently described representative embodiments. These common aspects and details may not be repeated in order to avoid obscuring the presently described representative embodiments.

Turning to FIG. 10C, first C module 1012 connects channels 1.1, 1.2, 1.3 and 1.4 to the first S module 1013 and the second S module 1015, and channels 2.1, 3.1, 3.2 and 4.1 are connected via a second C module 1017 to a third S module 1019 and a fourth S module 1021. As shown, power units PU1-9 and PU 13-PU18 can be connected only to one 4×6 block of switches. However, feedthrough connections 1023 enable the connections of power units PU10, PU11 and PU12 to the first and second blocks of switches. Accordingly, four outputs of each of the power routers get connected to the rows of the matrix, and thus to each channel. The power units are then connected with power units PU1-PU12 are connected to a first power router, and power units PU13-PU 18 are connected to a second power. However, power units PU10, PU 11 and PU12 are connected to the first and second power routers via the feedthrough connections 1023. Accordingly, the modular design of the representative embodiments described above provide a flexible way to effect the necessary connections to form a switch matrix based on blocks of switches from the switch modules. With these connections the difference between FIG. 8D and FIG. 8E are realized physically. The shift of 9 power units is done by connecting PU10-18 instead of PU1-9.

FIG. 11A is a perspective view of a switch module 1100 comprising two 4×3 mounting plates 1102, 1104 in accordance with a representative embodiment. Various aspects and details of the representative embodiments described above in connection with FIGS. 1-10C, including allocation of power and switching, may be common to the presently described representative embodiments. These common aspects and details may not be repeated in order to avoid obscuring the presently described representative embodiments. Each mounting plate houses a PLC satellite for switching the switches such as shown and described in connection with the representative embodiments described in connection with FIG. 9D.

FIG. 11B is a perspective view of a mounting plate 1102 shown in FIG. 11A. Various aspects and details of the representative embodiments described above in connection with FIGS. 1-11A, including allocation of power and switching, may be common to the presently described representative embodiments. These common aspects and details may not be repeated in order to avoid obscuring the presently described representative embodiments.

As shown, a matrix of switches 1114 connected view vertical conductors 1110 and horizontal conductors 1112 are show. The mounting plate is adapted to be installed in the switching module in order to provide one of the 4×3 blocks of switches use to make up the desired switching matrix. Moreover, there are also the feed-through contacts on the top and the PLC Satellite on the bottom.

FIG. 12A is a perspective view of the switch module of FIG. 11A connected to a connection (“C”) module 1202 of a representative embodiment. Various aspects and details of the representative embodiments described above in connection with FIGS. 1-11A, including allocation of power and switching, may be common to the presently described representative embodiments. These common aspects and details may not be repeated in order to avoid obscuring the presently described representative embodiments.

As shown, the connection module comprises electrical bars or buses 1204 to provide current to the DUT's (not shown in FIG. 1) during testing. As noted above, additional S modules may be added to the S module 1201 and the C module 1202 to provide the required connections to effect testing. Notably, at the end of the electrical bars, fuses can be provided to prevent overcurrent in an emergent situation.

FIG. 12B is a perspective view of a plurality of switch modules connected to a connection module to provide a switch matrix comprises a plurality of blocks of switches in accordance with a representative embodiment. Various aspects and details of the representative embodiments described above in connection with FIGS. 1-11A, including allocation of power and switching, may be common to the presently described representative embodiments. These common aspects and details may not be repeated in order to avoid obscuring the presently described representative embodiments.

As shown, S modules 1201 are provided and are connected to the C module 1202 via the electrical bars or buses 1204 as shown. This shows the modular aspects of the representative embodiments, which fosters adaptability for testing as DUT configurations are changed for testing.

Although power allocation manager for intelligent power allocation for high-power test laboratories have been described with reference to several illustrative embodiments, it is understood that the words that have been used are words of description and illustration, rather than words of limitation. Changes may be made within the purview of the appended claims, as presently stated and as amended, without departing from the scope and spirit of power allocation manager for intelligent power allocation for high-power test laboratories in its aspects. Although power allocation manager for intelligent power allocation for high-power test laboratories has been described with reference to particular means, materials and embodiments, power allocation manager for intelligent power allocation for high-power test laboratories is not intended to be limited to the particulars disclosed; rather power allocation manager for intelligent power allocation for high-power test laboratories extends to all functionally equivalent structures, methods, and uses such as are within the scope of the appended claims.

The illustrations of the embodiments described herein are intended to provide a general understanding of the structure of the various embodiments. The illustrations are not intended to serve as a complete description of all of the elements and features of the disclosure described herein. Many other embodiments may be apparent to those of skill in the art upon reviewing the disclosure. Other embodiments may be utilized and derived from the disclosure, such that structural and logical substitutions and changes may be made without departing from the scope of the disclosure. Additionally, the illustrations are merely representational and may not be drawn to scale. Certain proportions within the illustrations may be exaggerated, while other proportions may be minimized. Accordingly, the disclosure and the figures are to be regarded as illustrative rather than restrictive.

One or more embodiments of the disclosure may be referred to herein, individually and/or collectively, by the term “invention” merely for convenience and without intending to voluntarily limit the scope of this application to any particular invention or inventive concept. Moreover, although specific embodiments have been illustrated and described herein, it should be appreciated that any subsequent arrangement designed to achieve the same or similar purpose may be substituted for the specific embodiments shown. This disclosure is intended to cover any and all subsequent adaptations or variations of various embodiments. Combinations of the above embodiments, and other embodiments not specifically described herein, will be apparent to those of skill in the art upon reviewing the description.

The Abstract of the Disclosure is provided to comply with 37 C.F.R. § 1.72(b) and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The preceding description of the disclosed embodiments is provided to enable any person skilled in the art to practice the concepts described in the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

1. A battery pack test system, comprising:
a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test (DUT);
a plurality of test bench control units each configured to interface with the power router and a different corresponding device under test, and each comprising a plurality of measurement sensors for measuring characteristics of the corresponding DUT; and
a switch matrix comprising blocks of switches having a predetermined number of columns and a predetermined number of rows, wherein each row provides connections to a DUT and each column provides connections to one of the individual power units so that no two DUT's are connected together and/or no two connections are made in a same column.

2. The battery pack test system of claim 1, wherein the switch matrix comprises redundant blocks of switches comprising the predetermined number of rows and the predetermined number of columns.

3. The battery pack test system of claim 1, wherein the predetermined number of rows comprises four switches, and the predetermined number of columns comprises three switches or six switches.

4. The battery pack test system of claim 1, wherein the power allocation manager comprises a programmable logic controller (PLC) in the power router, the PLC being adapted to engage and disengage switches selectively.

5. The battery pack test system of claim 4, wherein PLC is adapted to monitor the plurality of switches to avoid certain connections of the switches.

6. The battery pack test system of claim 5, wherein the PLC is adapted to control the switches so that no two switches in a column of the predetermined number of columns of switches are engaged at the same time.

7. The battery pack test system of claim 5, wherein the PLC is adapted to disengage a row of switches of the predetermined number of switches when maintenance or updating of the battery pack test system is being done.

8. The battery pack test system of claim 5, wherein the PLC is adapted to disengage all rows of the plurality of rows when an emergent situation is encountered.

9. The battery pack test system of claim 1, wherein each test bench control unit comprises a plurality of contactors configured to connect the power allocation manager to the corresponding device under test and to disconnect the power allocation manager from the corresponding DUT.

10. The battery pack test system of claim 1, wherein each test bench control unit is reconfigurable to adapt to multiple different devices under test.

11. A battery pack test system, comprising:
a power allocation manager comprising a power cluster with a plurality of power units and a power router that routes power from each of the plurality of power units, wherein the power allocation manager is configured to dynamically switch allocations of power from individual power units of the plurality of power units to a plurality of test channels each connected to a different device under test (DUT);
a plurality of test bench control units each configured to interface with the power router and a different corresponding device under test, and each comprising a plurality of measurement sensors for measuring characteristics of the corresponding DUT; and
a switch module comprising a switch matrix comprising blocks of switches having a predetermined number of columns and a predetermined number of rows, wherein each row provides connections to a DUT and each column provides connections to one of the individual power units, so that no two DUT's are connected together and/or no two connections are made in a same column.

12. The battery pack test system of claim 11, further comprising a connection module selectively connected to the switch module, wherein the connection module delivers electrical power to the DUTs.

13. The battery pack test system of claim 11, wherein the switch module is a first switch module, the switch matrix is a first switch matrix, the predetermined number of rows is a first predetermined number of rows, the predetermined number of columns, and the DUT is a first DUT, the battery pack test system further comprising: a second switch module comprising a second switch matrix comprising blocks of second switches having a second predetermined number of columns and a second predetermined number of rows, wherein each row provides connections to a second DUT and each column provides connections to one of the individual power units.

14. The battery pack test system of claim 11, wherein the switch matrix comprises redundant blocks of switches comprising the predetermined number of rows and the predetermined number of columns.

15. The battery pack test system of claim 11, wherein the predetermined number of rows comprises four switches, and the predetermined number of columns comprises three switches or six switches.

16. The battery pack test system of claim 11, wherein the power allocation manager comprises a programmable logic controller (PLC) in the power router, the PLC being adapted to engage and disengage switches selectively.

17. The battery pack test system of claim 16, wherein PLC is adapted to monitor the plurality of switches to avoid certain connections of the switches.

18. The battery pack test system of claim 17, wherein the PLC is adapted to control the switches so that no two switches in a column of the predetermined number of columns of switches are engaged at the same time.

19. The battery pack test system of claim 17, wherein the PLC is adapted to disengage a row of switches of the predetermined number of switches when maintenance or updating of the battery pack test system is being done.

20. The battery pack test system of claim 17, wherein the PLC is adapted to disengage all rows of the plurality of rows when an emergent situation is encountered.
